(19) United States
(12) Patent Application Publication
(10) Pub. No.: US 2026/0013273 A1
(43) Pub. Date: Jan. 8, 2026

(54) LIGHT EMITTING DEVICE AND MANUFACTURING METHOD THEREOF

(71) Applicant: Japan Display Inc., Tokyo (JP)

(72) Inventors: Masanobu IKEDA, Tokyo (JP); Masumi NISHIMURA, Tokyo (JP)

(73) Assignee: Japan Display Inc., Tokyo (JP)

(21) Appl. No.: 19/259,037

(22) Filed: Jul. 3, 2025

Related U.S. Application Data
(63) Continuation of application No. PCT/JP2023/045905, filed on Dec. 21, 2023.

(30) Foreign Application Priority Data
Jan. 25, 2023 (JP) 2023-009472

(51) Int. Cl. H10H 20/825; H10H 20/01; H10H 20/815; H10H 20/831; H10H 20/833; H10H 20/857

(52) U.S. Cl. CPC H10H 20/825; H10H 20/01335; H10H 20/032; H10H 20/0364; H10H 20/815; H10H 20/8312; H10H 20/833; H10H 20/857

(57) ABSTRACT

A light emitting device includes a substrate, a buffer layer over the substrate, a nitride semiconductor layer over the buffer layer, a first n-type nitride semiconductor layer over the nitride semiconductor layer, a metal layer over the first n-type nitride semiconductor layer, a second n-type nitride semiconductor layer over the metal layer, a light emitting layer over the second n-type nitride semiconductor layer, and a p-type nitride semiconductor layer over the light emitting layer. The metal layer has a pattern shape in which a portion of the first n-type nitride semiconductor layer is exposed. The second n-type nitride semiconductor layer is in contact with the portion of the first n-type nitride semiconductor layer exposed from the metal layer.

### CROSS-REFERENCE TO RELATED APPLICATIONS

This application is a Continuation of International Patent Application No. PCT/JP2023/045905, filed on Dec. 21, 2023, which claims the benefit of priority to Japanese Patent Application No. 2023-009472, filed on Jan. 25, 2023, the entire contents of which are incorporated herein by reference.

### FIELD

An embodiment of the present invention relates to a light emitting device using a nitride semiconductor. Further, an embodiment of the present invention relates to a method for manufacturing a light emitting device using a nitride semiconductor.

### BACKGROUND

Japanese laid-open patent publication No. 2000-124140 discloses a method for forming a gallium nitride film on a glass substrate. Further, Japanese laid-open patent publication No. 2018-168029 discloses that when forming a gallium nitride film on a buffer layer, an insulating film having an opening portion is provided on the buffer layer, and crystalline dislocations of the gallium nitride are reduced by epitaxial growth in the lateral direction through the opening portion.

### SUMMARY

A light emitting device according to an embodiment of the present invention includes a substrate, a buffer layer over the substrate, a nitride semiconductor layer over the buffer layer, a first n-type nitride semiconductor layer over the nitride semiconductor layer, a metal layer over the first n-type nitride semiconductor layer, a second n-type nitride semiconductor layer over the metal layer, a light emitting layer over the second n-type nitride semiconductor layer, and a p-type nitride semiconductor layer over the light emitting layer. The metal layer has a pattern shape in which a portion of the first n-type nitride semiconductor layer is exposed. The second n-type nitride semiconductor layer is in contact with the portion of the first n-type nitride semiconductor layer exposed from the metal layer.

A method for manufacturing a light emitting device according to an embodiment of the present invention includes the steps of forming a buffer layer over a substrate, forming a first n-type nitride semiconductor layer over the buffer layer, forming a metal layer having a pattern shape in which a portion of the first n-type nitride semiconductor layer is exposed, over the first nitride semiconductor layer, forming a second n-type nitride semiconductor layer in contact with the portion of the first n-type nitride semiconductor layer exposed from the metal layer, over the metal layer, forming a light emitting layer over the second n-type nitride semiconductor layer, and forming a p-type nitride semiconductor layer over the light emitting layer.

### BRIEF DESCRIPTION OF DRAWINGS

FIG. 1 is a schematic plan view showing a configuration of a light emitting device according to an embodiment of the present invention.

FIG. 2 is a circuit diagram showing a circuit configuration of a pixel (a pixel circuit) of a light emitting device according to an embodiment of the present invention.

FIG. 3 is a schematic top view showing a configuration of a light emitting element of a light emitting device according to an embodiment of the present invention.

FIG. 4 is a schematic cross-sectional view showing a configuration of a light emitting element of a light emitting device according to an embodiment of the present invention.

FIG. 5 is a schematic plan view illustrating a pattern shape of a metal layer in a light emitting element of a light emitting device according to an embodiment of the present invention.

FIG. 6 is a schematic plan view illustrating a pattern shape of a metal layer in a light emitting element of a light emitting device according to an embodiment of the present invention.

FIG. 7 is a schematic diagram showing a configuration of a film formation apparatus for forming a nitride semiconductor film in a light emitting device according to an embodiment of the present invention.

FIG. 8 is a block diagram showing connections of a control unit of a film formation apparatus for forming a nitride semiconductor film in a light emitting device according to an embodiment of the present invention.

FIG. 9 is a flow chart showing a method for forming a nitride semiconductor film using a film formation apparatus in a manufacturing method for a light emitting device according to an embodiment of the present invention.

FIG. 10 is a sequence diagram showing a timing of control by a control unit of a film formation apparatus in a manufacturing method for a light emitting device according to an embodiment of the present invention.

FIG. 11 is a flowchart showing a method for manufacturing a light emitting element of a light emitting device according to an embodiment of the present invention.

FIG. 12 is a schematic cross-sectional view showing a method for manufacturing a light emitting element of a light-emitting device according to an embodiment of the present invention.

FIG. 13 is a schematic cross-sectional view showing a method for manufacturing a light emitting element of a light-emitting device according to an embodiment of the present invention.

FIG. 14 is a schematic cross-sectional view showing a method for manufacturing a light emitting element of a light-emitting device according to an embodiment of the present invention.

FIG. 15 is a schematic cross-sectional view showing a method for manufacturing a light emitting element of a light-emitting device according to an embodiment of the present invention.

FIG. 16 is a schematic cross-sectional view showing a method for manufacturing a light emitting element of a light-emitting device according to an embodiment of the present invention.

FIG. 17 is a schematic cross-sectional view showing a method for manufacturing a light emitting element of a light-emitting device according to an embodiment of the present invention.

FIG. 18 is a schematic cross-sectional view showing a method for manufacturing a light emitting element of a light-emitting device according to an embodiment of the present invention.

FIG. 19 is a schematic cross-sectional view showing a method for manufacturing a light emitting element of a light-emitting device according to an embodiment of the present invention.

FIG. 20 is a schematic cross-sectional view showing a method for manufacturing a light emitting element of a light-emitting device according to an embodiment of the present invention.

FIG. 21 is a schematic cross-sectional view showing a method for manufacturing a light emitting element of a light-emitting device according to an embodiment of the present invention.

FIG. 22 is a schematic cross-sectional view showing a method for manufacturing a light emitting element of a light-emitting device according to an embodiment of the present invention.

FIG. 23 is a schematic cross-sectional view showing a method for manufacturing a light emitting element of a light-emitting device according to an embodiment of the present invention.

FIG. 24 is a schematic cross-sectional view showing a configuration of a light emitting element of a light emitting device according to an embodiment of the present invention.

FIG. 25 is a schematic cross-sectional view showing a configuration of a light emitting element of a light emitting device according to an embodiment of the present invention.

FIG. 26 is a schematic cross-sectional view showing a configuration of a light emitting element of a light emitting device according to an embodiment of the present invention.

FIG. 27 is a schematic plan view illustrating a pattern shape of a metal layer in a light emitting element of a light emitting device according to an embodiment of the present invention.

FIG. 28 is a schematic plan view showing a pattern shape of a metal layer in a light emitting element of a light emitting device according to an embodiment of the present invention.

FIG. 29 is a schematic plan view illustrating a pattern shape of a metal layer in a light emitting element of a light emitting device according to an embodiment of the present invention.

FIG. 30 is a schematic plan view illustrating a pattern shape of a metal layer in a light emitting element of a light emitting device according to an embodiment of the present invention.

### DESCRIPTION OF EMBODIMENTS

Since a gallium nitride film is formed by metal-organic chemical vapor deposition (MOCVD) in the Japanese laid-open patent publication Nos. 2000-124140 and 2018-168029, it is difficult to form a high-quality gallium nitride film usable in a light emitting diode on a large-area glass substrate.

An embodiment of the present invention can provide a light emitting device using a nitride semiconductor film formed on a large-area substrate. Further, an embodiment of the present invention can provide a method for manufacturing a light emitting device including a nitride semiconductor film formed on a large-area substrate.

Hereinafter, each of the embodiments of the present invention is described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments. However, the illustrated shapes are merely examples and are not intended to limit the interpretation of the present invention.

In the present specification, the expression “a includes A, B, or C,” “a includes any of A, B, or C,” “a includes one selected from a group consisting of A, B and C,” and the like does not exclude the case where a includes a plurality of combinations of A to C unless otherwise specified. Further, these expressions do not exclude the case where a includes other components.

In the present specification, although the phrase “on” or “over” or “under” or “below” is used for convenience of explanation, in principle, the direction from a substrate toward a structure is referred to as “on” or “over” with reference to a substrate in which the structure is formed. Conversely, the direction from the structure to the substrate is referred to as “under” or “below.” Therefore, in the expression of “a structure over a substrate,” one surface of the structure in the direction facing the substrate is the bottom surface of the structure and the other surface is the upper surface of the structure. In addition, the expression of “a structure over a substrate” only explains the vertical relationship between the substrate and the structure, and another member may be placed between the substrate and the structure. Furthermore, the term “on” or “over” or “under” or “below” means the order of stacked layers in the structure in which a plurality of layers is stacked, and may not be related to the position in which layers overlap in a plan view.

In the specification, terms such as “first,” “second,” or “third” attached to each configuration are convenient terms used to distinguish each component, and have no further meaning unless otherwise explained.

In the specification and the drawings, the same reference numerals may be used when multiple components are identical or similar in general, and reference numerals with an upper-case letter of the alphabet may be used when the multiple components are distinguished. Further, reference numerals with a hyphen and a natural number may be used when multiple portions of one component are distinguished.

In the specification, the terms “film” and “layer” can be optionally interchanged with one another.

In the specification, the term “nitride semiconductor” refers to a semiconductor containing nitrogen in III-V group semiconductors. For example, the “nitride semiconductor” is gallium nitride (GaN) or indium gallium nitride (InGaN). In the specification, when simply referring to a “nitride semiconductor,” the term “nitride semiconductor” means an undoped nitride semiconductor. Further, a nitride semiconductor to which an impurity is added and which has conductivity is referred to as a “p-type nitride semiconductor” or an “n-type nitride semiconductor.”

In the specification, the term “light emitting device” refers to any device including a light emitting element. For example, the term “light emitting device” includes a lighting device that irradiates light to a specific location, and a display device that displays a visual image or video. Further, the term “light emitting device” may also consist of only a light emitting element (e.g., an LED chip).

In the specification, a cation and an anion may be referred to as a positive ion and a negative ion, respectively.

The following embodiments can be combined with each other as long as there is no technical contradiction.

### First Embodiment

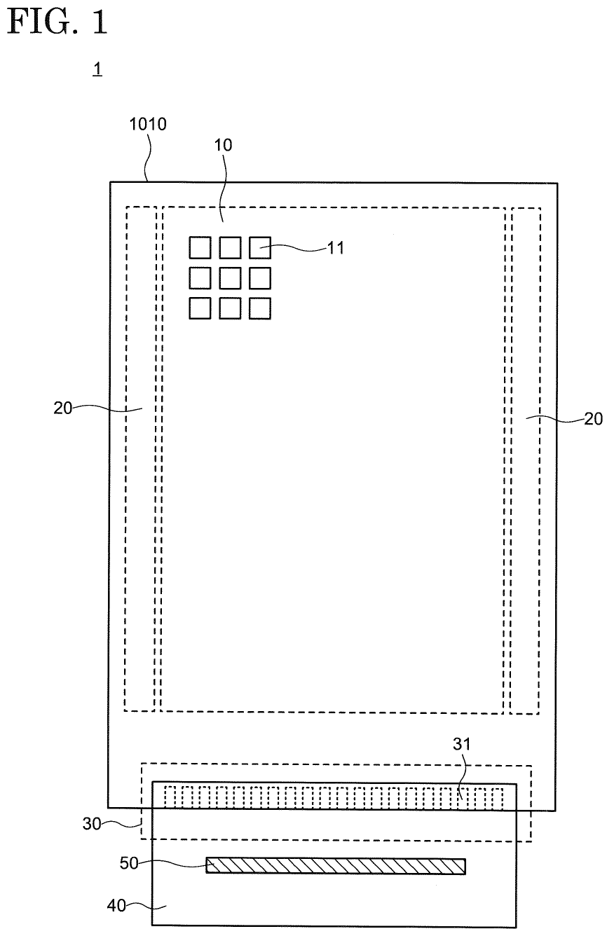

A light emitting device 1 according to an embodiment of the present invention is described with reference to FIGS. 1 to 23. In the present embodiment, although the light emitting device 1 is described as a display device, the light emitting device 1 is not limited to a display device.

### [1. Overview of Configuration of Light Emitting Device 1]

FIG. 1 is a schematic plan view showing a configuration of the light emitting device 1 according to an embodiment of the present invention.

In the light emitting device 1, a display portion 10, a drive circuit portion 20, and a terminal portion 30 are provided on a substrate 1010. The driver circuit portion 20 is provided around the display portion 10 and can control the display portion 10. For example, the drive circuit portion 20 includes a scan drive circuit. Further, the terminal portion 30 is provided at an end portion of the substrate 1010 and can supply a signal or power to the light emitting device 1. For example, the terminal portion 30 includes terminals 31 connected to a flexible printed circuit substrate 40. A driver IC 50 may be provided on the flexible printed circuit substrate 40.

The display portion 10 can display an image or video, and includes a plurality of pixels 11 arranged in a matrix. However, the arrangement of the plurality of pixels 11 is not limited to a matrix. For example, the plurality of pixels 11 can also be arranged in a zigzag pattern.

### [2. Configuration of Pixel 11]

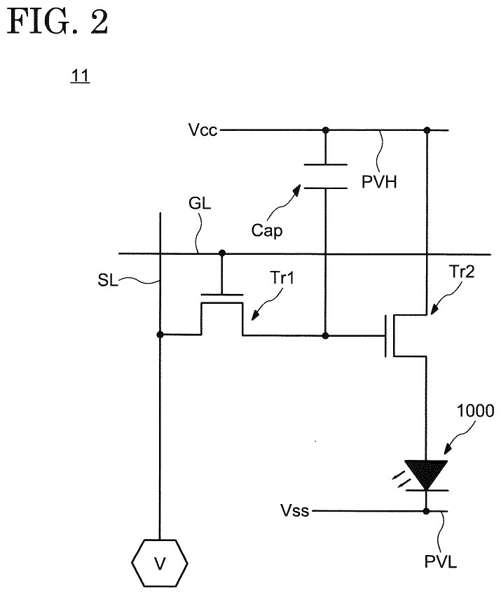

FIG. 2 is a circuit diagram of the pixel 11 (a pixel circuit) of the light emitting device 1 according to an embodiment of the present invention. As shown in FIG. 2, the pixel 11 includes a first transistor Tr1, a second transistor Tr2, a light emitting element 1000, and a capacitive element Cap.

The first transistor Tr1 can function as a select transistor. That is, the conduction state of the first transistor Tr1 is controlled by a scanning line GL. A gate, a source, and a drain of the first transistor Tr1 are electrically connected to the scan line GL, a signal line SL, and a gate of the second transistor Tr2, respectively.

The second transistor Tr2 can function as a drive transistor. That is, the second transistor Tr2 controls a light emission brightness of the light emitting element 1000. The gate, a source, and a drain of the second transistor Tr2 are electrically connected to the source of the first transistor Tr1, a driving power supply line PVH, and an anode (p-type electrode) of the light emitting element 1000, respectively. A predetermined potential (Vcc) is supplied to the power supply line PVH.

One capacitive electrode of the capacitive element Cap is electrically connected to the gate of the second transistor Tr2 and the drain of the first transistor Tr1. Further, the other capacitive electrode of the capacitive element Cap is electrically connected to the power supply line PVH.

The anode of the light emitting element 1000 is connected to the drain of the second transistor Tr2. Further, a cathode (n-type electrode) of the light emitting element 1000 is connected to a reference power supply line PVL.

On or off of the light emission of the light emitting element 1000 of each pixel 11 or the light emission time or light emission brightness are controlled by signals input to the scanning line GL and the signal line SL. However, the pixel circuit in the pixel 11 is not limited to the configuration shown in FIG. 2. The light emitting device 1 may have any configuration that allows the light emitting element 1000 to be controlled via wiring (e.g., the scanning line GL, the signal line SL, the power supply line PVH, and the reference power supply line PVL) arranged in the display portion 10.

In addition, the light emitting device 1 may have a configuration that does not include a transistor.

### [3. Configuration of Light Emitting Element 1000]

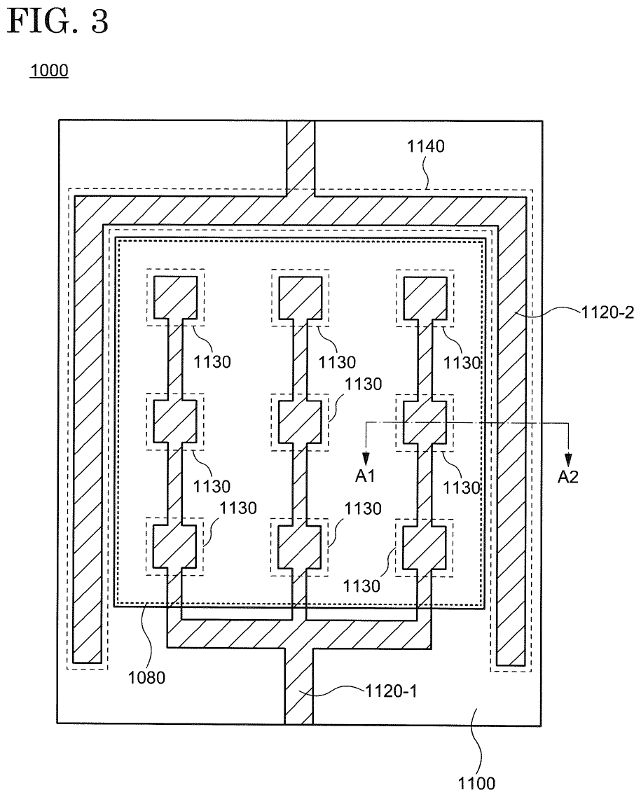

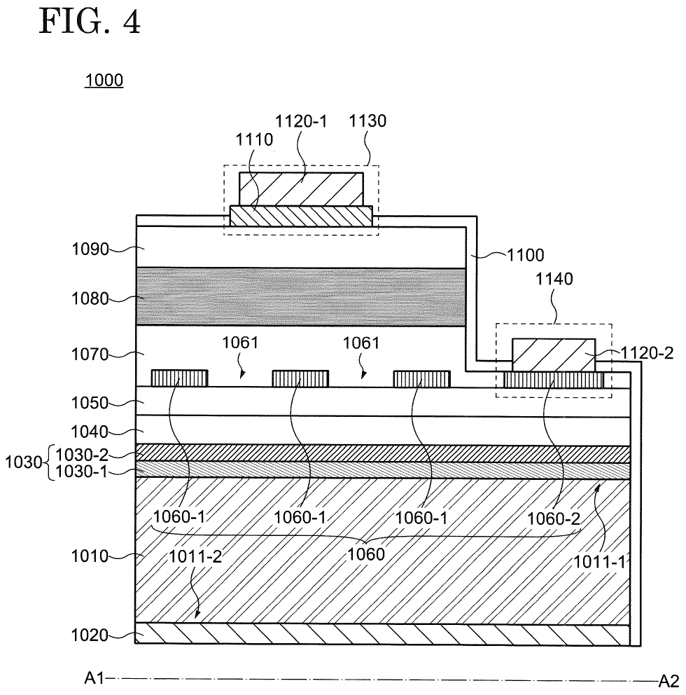

FIG. 3 is a schematic top view showing a configuration of the light emitting element 1000 of the light emitting device 1 according to an embodiment of the present invention. Further, FIG. 4 is a schematic cross-sectional view showing a configuration of the light emitting element 1000 of the light emitting device 1 according to an embodiment of the present invention. Specifically, FIG. 4 is a partial cross-sectional view of the light emitting element 1000 cut along a line A1-A2 shown in FIG. 3.

The light emitting element 1000 shown in FIGS. 3 and 4 is a so-called light emitting diode (LED). As shown in FIG. 4, the light emitting element 1000 includes a substrate 1010, a compensation layer 1020, a buffer layer 1030 (a first buffer layer 1030-1 and a second buffer layer 1030-2), a nitride semiconductor layer 1040, a first n-type nitride semiconductor layer 1050, a metal layer 1060 (a first metal layer 1060-1 and a second metal layer 1060-2), a second n-type nitride semiconductor layer 1070, a light emitting layer 1080, a p-type nitride semiconductor layer 1090, a protective layer 1100, a transparent electrode layer 1110, a first conductive layer 1120-1, and a second conductive layer 1120-2. In the light emitting element 1000, the p-type electrode 1130 includes a transparent electrode layer 1110 and a first conductive layer 1120-1, and the n-type electrode 1140 includes a second metal layer 1060-2 and a second conductive layer 1120-2. The p-type electrode 1130 is provided over and in contact with the p-type nitride semiconductor layer 1090. The n-type electrode 1140 is provided over and in contact with the first n-type nitride semiconductor layer 1050. The n-type electrode 1140 may be in contact with the second n-type nitride semiconductor layer 1070.

The buffer layer 1030, the nitride semiconductor layer 1040, the first n-type nitride semiconductor layer 1050, the metal layer 1060, the second n-type nitride semiconductor layer 1070, the light emitting layer 1080, the p-type nitride semiconductor layer 1090, the p-type electrode 1130, and the n-type electrode 1140 are provided over a first surface 1011-1 of the substrate 1010. On the other hand, the compensation layer 1020 is provided on a second surface 1011-2 opposite to the first surface 1011-1 of the substrate 1010.

In FIG. 3, the light emitting layer 1080 under the protective layer 1100 is shown by a dotted line, for convenience. As shown in FIG. 3, in a top view, the plurality of p-type electrodes 1130 are arranged so as to overlap the light emitting layer. That is, the first conductive layer 1120-1 included in the plurality of p-type electrodes 1130 is formed so as to overlap the light emitting layer 1080. Further, the first conductive layer 1120-1 extends so that the plurality of p-type electrodes 1130 are electrically connected to each other. In a top view, the n-type electrode 1140 is arranged around the light emitting layer 1080 without overlapping the light emitting layer 1080. The second conductive layer 1120-2 included in the n-type electrode 1140 has the same configuration as the n-type electrode 1140.

The first conductive layer 1120-1 is electrically connected to the power supply line PVH through the second transistor Tr2. The second conductive layer 1120-2 is electrically connected to the reference power supply line PVL. In this case, the power supply line PVH and the reference power supply line PVL may be formed in the same layer as the first conductive layer 1120-1 and the second conductive layer 1120-2, respectively. That is, in the light-emitting device 1 according to the present invention, the first conductive layer 1120-1 including the p-type electrode 1130 and the second conductive layer 1120-2 including the n-type electrode 1140 can be used as wiring arranged in the display portion 10.

Next, each component included in the light emitting device 1000 is described in detail.

### [3-1. Configuration of Substrate 1010]

The substrate 1010 is an amorphous substrate capable of being made with a large area. For example, a glass substrate can be used as the substrate 1010. Although the glass substrate is generally amorphous and does not have a crystalline structure, a crystalline structure may exist in a fine region. The upper limit of the thermal expansion coefficient of the glass substrate is less than 4.2×10⁻⁶/K, and preferably less than 4.0×10⁻⁶/K. The lower limit of the thermal expansion coefficient of the glass substrate is greater than 3.0×10⁻⁶/K, and preferably greater than 3.5×10⁻⁶/K. The light emitting device 1 is manufactured at a temperature less than 650° C. Therefore, it is preferable that the glass substrate has heat resistance at least at a temperature of 650° C. The lower limit of the glass transition point of the glass substrate is, for example, greater than or equal to 650° C., and preferably greater than or equal to 720° C. Further, the upper limit of the glass transition point of the glass substrate is, for example, less than or equal to 900° C., and preferably less than or equal to 810° C. For the same reason, the lower limit of the softening point of the glass substrate is, for example, greater than or equal to 900° C., and preferably greater than or equal to 950° C. Further, the upper limit of the softening point of the glass substrate is, for example, less than or equal to 1150° C., and preferably less than or equal to 1050° C.

The glass material used as the glass substrate preferably has a low content of alkali metals in order to prevent contamination of the light emitting layer 1080. For example, the content of alkali metals in the glass substrate is less than or equal to 0.1 mass %. For example, an amorphous glass material made of aluminoborosilicate glass or aluminosilicate glass is used as the glass substrate. The amorphous glass substrate is used in a liquid crystal display and an organic electroluminescence (organic EL) display, and a large-area glass substrate called a mother glass are provided on the market. Therefore, by selecting a highly versatile glass substrate as the substrate 1010 of the light-emitting element 1000, the light emitting device 1 can be manufactured at low cost using a large-area substrate.

Although the thickness of the substrate 1010 is not particularly limited to a specific thickness, it is preferable that the thickness of the substrate 1010 is sufficiently larger than the total thickness of the first n-type nitride semiconductor layer 1050, the second n-type nitride semiconductor layer 1070, the light emitting layer 1080, and the p-type nitride semiconductor layer 1090 from the viewpoint of reducing warpage of the substrate 1010. For example, the substrate 1010 has a thickness greater than or equal to 50 times the total thickness of the first n-type nitride semiconductor layer 1050, the second n-type nitride semiconductor layer 1070, the light emitting layer 1080, and the p-type nitride semiconductor layer 1090. For example, the substrate 1010 has a thickness of 0.5 mm to 1.0 mm.

In addition, although not shown in the figures, a base layer may be formed on the substrate 1010 to prevent diffusion of impurities (e.g., moisture or sodium (Na)) from the substrate 1010. For example, silicon oxide (SiOₓ) or silicon nitride (SiNₓ) may be used for the base layer. The base layer may be a single film or a laminated film.

### [3-2. Configuration of Compensation Layer 1020]

The compensation layer 1020 is preferably provided in order to reduce warpage of the substrate 1010. The compensation layer 1020 is formed on the second surface 1011-2 of the substrate 1010. The compensation layer 1020 can mitigate warpage of the substrate 1010 caused by a difference in the thermal expansion coefficient between the substrate 1010 and the nitride semiconductor layer 1040, the first n-type nitride semiconductor layer 1050, the second n-type nitride semiconductor layer 1070, the light emitting layer 1080, or the p-type nitride semiconductor layer 1090 by setting the thermal expansion coefficient within a predetermined range. The thermal expansion coefficient of the compensation layer 1020 is larger than that of the substrate 1010 and smaller than that of the nitride semiconductor layer 1040, the first n-type nitride semiconductor layer 1050, the second n-type nitride semiconductor layer 1070, the light emitting layer 1080, and the p-type nitride semiconductor layer 1090. For example, the lower limit of the thermal expansion coefficient of the compensation layer 1020 is greater than 4.0×10⁻⁶/K, and preferably greater than 4.1×10⁻⁶/K. For example, the upper limit of the thermal expansion coefficient of the compensation layer 1020 is less than 5.0×10⁻⁶/K, and preferably less than 4.6×10⁻⁶/K. However, the upper and lower limits of the thermal expansion coefficient of the compensation layer 1020 are not limited thereto.

As described above, the compensation layer 1020 is preferably formed on the second surface 1011-2 of the substrate 1010 In order to reduce warpage of the substrate 1010. The compensation layer 1020 can mitigate warpage of the substrate 1010 caused by a difference in the thermal expansion coefficient between the substrate 1010 and the nitride semiconductor layer 1040, the first n-type nitride semiconductor layer 1050, the second n-type nitride semiconductor layer 1070, the light emitting layer 1080, or the p-type nitride semiconductor layer 1090 by setting the thermal expansion coefficient within a predetermined range.

Further, since the compensation layer 1020 is in contact with the substrate 1010, heat can be efficiently and uniformly transferred to the entire substrate 1010 in the process of forming the nitride semiconductor layer 1040, the first n-type nitride semiconductor layer 1050, the second n-type nitride semiconductor layer 1070, the light emitting layer 1080, and the p-type nitride semiconductor layer 1090 over the substrate 1010 by setting the thermal conductivity to a predetermined value. As a result, the uniformity of the thicknesses of the nitride semiconductor layer 1040, the first n-type nitride semiconductor layer 1050, the second n-type nitride semiconductor layer 1070, the light emitting layer 1080, and the p-type nitride semiconductor layer 1090 can be improved. Therefore, the compensation layer 1020 can have a thermal conductivity that exceeds the thermal conductivity of the substrate 1010. Although the thermal conductivity of the compensation layer 1020 can be appropriately set depending on the material constituting the substrate 1010, the thermal conductivity of the compensation layer 1020 is, for example, greater than 10 W/m·K, preferably greater than 40 W/m. K.

The thermal conductivity of the compensation layer 1020 can be adjusted by adjusting the film density to a predetermined value. Although the relationship between the film density and the thermal conductivity varies depending on the material constituting the compensation layer 1020, the lower limit of the film density of the compensation layer 1020 is, for example, greater than or equal to 2.50 g/cm³, and preferably greater than or equal to 2.60 g/cm³. The upper limit of the film density of the compensation layer 1020 is less than or equal to 4.10 g/cm³, and preferably less than or equal to 4.00 g/cm³.

Although the material used for the compensation layer 1020 is not particularly limited to a certain material as long as it satisfies the above-described physical property values, it is preferable that the material is resistant to chemical treatment with acid or the like used in the manufacturing process of the light emitting element 1000. For example, an aluminum nitride film or an aluminum oxide film, or a laminated film of an aluminum nitride film and an aluminum oxide film can be used as the compensation layer 1020.

The thickness of the compensation layer 1020 is not particularly limited to a specific value, and is appropriately set according to the structure of the light emitting element 1000. However, from the viewpoint of reducing warpage of the substrate 1010, the compensation layer 1020 can be formed so as not to be excessively thin compared to the total thickness of the nitride semiconductor layer 1040, the first n-type nitride semiconductor layer 1050, the second n-type nitride semiconductor layer 1070, the light-emitting layer 1080, and the p-type nitride semiconductor layer 1090. For example, the compensation layer 1020 can have a thickness greater than or equal to 80% of the total thickness of the nitride semiconductor layer 1040, the first n-type nitride semiconductor layer 1050, the second n-type nitride semiconductor layer 1070, the light-emitting layer 1080, and the p-type nitride semiconductor layer 1090.

### [3-3. Configuration of the Buffer Layer 1030]

The buffer layer 1030 can control the crystal orientation of the nitride semiconductor layer 1040 and improve the crystallinity of the nitride semiconductor layer 1040. Specifically, the buffer layer 1030 can control the c-axis of the nitride semiconductor film formed on the buffer layer 1030 to grow in the film thickness direction. Although a nitride semiconductor having a hexagonal close-packed structure grows in the c-axis direction so as to minimize the surface energy, the crystal growth of the nitride semiconductor film in the c-axis direction is promoted when the nitride semiconductor film is formed on the buffer layer 1030. As a result, the nitride semiconductor layer 1040 formed on the buffer layer 1030 has a c-axis orientation.

The buffer layer 1030 is formed on the first surface 1011-1 of the substrate 1010. The buffer layer 1030 includes the first buffer layer 1030-1 and the second buffer layer 1030-2 over the first buffer layer 1030-1. That is, the buffer layer 1030 has a structure in which the first buffer layer 1030-1 and the second buffer layer 1030-2 are laminated. However, the configuration of the buffer layer 1030 is not limited thereto. The buffer layer 1030 may have a structure in which one of the first buffer layer 1030-1 and the second buffer layer 1030-2 is formed.

A material having a hexagonal close-packed structure, a face-centered cubic structure, or a structure equivalent thereto is used for each of the first buffer layer 1030-1 and the second buffer layer 1030-2. Here, a structure equivalent to a hexagonal close-packed structure or a face-centered cubic structure includes a crystal structure in which the c-axis is not 90° with respect to the a-axis and the b-axis. When each of the first buffer layer 1030-1 and the second buffer layer 1030-2 has the above-described structure, crystal growth in the c-axis direction of the nitride semiconductor film formed on the buffer layer 1030 is promoted, and the nitride semiconductor layer 1040 has high crystallinity with a c-axis orientation.

A conductive material can be used for the first buffer layer 1030-1. For example, titanium (Ti), titanium nitride (TiNₓ), titanium oxide (TiOₓ), graphene, zinc oxide (ZnO), magnesium diboride (MgB₂), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), or thorium (Th) can be used for the first buffer layer 1030-1. In particular, it is preferable to use titanium, graphene, or zinc oxide for the first buffer layer 1030-1.

Further, the conductive material of the first buffer layer 1030-1 may be silicon (Si), germanium (Ge), or an alloy thereof. Although silicon and germanium are semiconductor materials, silicon and germanium have higher conductivity than insulating materials described below. Therefore, in the specification, semiconductor materials such as silicon and germanium used for the first buffer layer 1030-1 are described as conductive materials.

In addition, when the light emitted from the light emitting element 1000 is extracted from the top surface, it is preferable that the light emitted from the light emitting layer 1080 is reflected by the first buffer layer 1030-1. In this case, a non-light-transmitting material is selected from the above-mentioned materials for the first buffer layer 1030-1.

An insulating material can be used for the second buffer layer 1030-2. For example, aluminum nitride (AlN), aluminum oxide (Al₂O₃), lithium niobate (LiNbO), BiLaTiO, SrFeO, BiFeO, BaFeO, ZnFeO, PMnN-PZT, or biological apatite (BAp) can be used for the second buffer layer 1030-2. In particular, it is preferable to use aluminum nitride for the second buffer layer 1030-2.

In addition, the first buffer layer 1030-1 may be made of the insulating material used in the second buffer layer 1030-2. For example, AlₓO_{y} (1≤x≤2, 1≤y≤3) can be used for the first buffer layer 1030-1.

The thickness of each of the first buffer layer 1030-1 and the second buffer layer 1030-2 are not particularly limited to a specific value.

### [3-4. Configuration of Nitride Semiconductor Layer 1040]

Although the first n-type nitride semiconductor layer 1050 can be formed directly on the buffer layer 1030, the first n-type nitride semiconductor layer 1050 thus formed is likely to have a large number of crystal dislocations. Therefore, the nitride semiconductor layer 1040 is formed on the buffer layer 1030 in order to reduce crystal dislocations in the first n-type nitride semiconductor layer 1050. For example, a nitride semiconductor film such as a gallium nitride film can be used as the nitride semiconductor layer 1040.

The thickness of the nitride semiconductor layer 1040 is not particularly limited to a specific value.

### [3-5. Configurations of First N-Type Nitride Semiconductor Layer 1050 and Second N-Type Nitride Semiconductor Layer 1070]

Each of the first n-type nitride semiconductor layer 1050 and the second n-type nitride semiconductor layer 1070 has electronic conductivity and can transport electrons to the light emitting layer 1080. In each of the first n-type nitride semiconductor layer 1050 and the second n-type nitride semiconductor layer 1070, impurities such as silicon (Si) or germanium (Ge) are added to impart n-type conductivity to the nitride semiconductor film. That is, an n-type nitride semiconductor film in which silicon or germanium is added to the nitride semiconductor film can be used as each of the first n-type nitride semiconductor layer 1050 and the second n-type nitride semiconductor layer 1070. For example, a gallium nitride film in which silicon or germanium is added can be used as each of the first n-type nitride semiconductor layer 1050 and the second n-type nitride semiconductor layer 1070. In addition, compared to germanium, silicon reacts with nitrogen more easily to form silicon nitride. Since silicon nitride in an n-type nitride semiconductor film reduces electrical conductivity, germanium is more preferable than silicon as an impurity in an n-type nitride semiconductor film.

It is preferable that the same nitride semiconductor is used for the first n-type nitride semiconductor layer 1050 and the second n-type nitride semiconductor layer 1070. In this case, in a part of the second n-type nitride semiconductor layer 1070, a nitride semiconductor film is formed by homoepitaxial growth from the first n-type nitride semiconductor layer 1050 through an opening portion 1061, and has high crystallinity.

The thickness of each of the first n-type nitride semiconductor layer 1050 and the second n-type nitride semiconductor layer 1070 is not particularly limited to a specific value. However, the thickness of the first n-type nitride semiconductor layer 1050 is preferably greater than or equal to 50 nm and less than 500 nm, and the thickness of the second n-type nitride semiconductor layer 1070 is preferably greater than or equal to 500 nm and less than or equal to 3000 nm.

### [3-6. Configuration of P-Type Nitride Semiconductor Layer 1090]

The p-type nitride semiconductor layer 1090 has hole conductivity and can transport holes to the light emitting layer 1080. In the p-type nitride semiconductor layer 1090, impurities such as magnesium (Mg) are added to impart p-type conductivity to the nitride semiconductor film. That is, a p-type nitride semiconductor film in which magnesium is added to a nitride semiconductor film can be used as the p-type nitride semiconductor layer 1090. For example, a gallium nitride film in which magnesium is added can be used as the p-type nitride semiconductor layer 1090. In addition, zinc (ZnO) can also be used as an impurity for the p-type nitride semiconductor layer 1090.

The thickness of the p-type nitride semiconductor layer 1090 is not particularly limited to a specific value.

### [3-7. Configuration of Light Emitting Layer 1080]

The light emitting layer 1080 can emit light by recombining electrons transported from the second n-type nitride semiconductor layer 1070 and holes transported from the p-type nitride semiconductor layer 1090. The light emitting layer 1080 has a multiple quantum well (MQW) structure. For example, a laminated film in which gallium nitride films and indium gallium nitride films are alternately laminated can be used as the light emitting layer 1080.

### [3-8. Configuration of Protective Layer 1100]

The protective layer 1100 covers the first n-type nitride semiconductor layer 1050, the second n-type nitride semiconductor layer 1070, the light emitting layer 1080, and the p-type nitride semiconductor layer 1090, and can suppress the influence of the external atmosphere on the first n-type nitride semiconductor layer 1050, the second n-type nitride semiconductor layer 1070, the light emitting layer 1080, and the p-type nitride semiconductor layer 1090. For example, a silicon oxide film or silicon nitride film, or a laminated film of silicon oxide and silicon nitride can be used as the protective layer 1100.

The thickness of the protective layer 1100 is not particularly limited to a specific value.

### [3-9. Configuration of Metal Layer 1060]

The metal layer 1060 is formed in contact with the first n-type nitride semiconductor layer 1050. The metal layer 1060 includes the first metal layer 1060-1 and the second metal layer 1060-2. In a plan view, although the first metal layer 1060-1 overlaps the light emitting layer 1080, the second metal layer 1060-2 does not overlap the light emitting layer 1080.

The first metal layer 1060-1, which has a lower resistivity than the first n-type nitride semiconductor layer 1050, is in contact with the first n-type nitride semiconductor layer 1050, thereby decreasing the effective resistivity of the first n-type nitride semiconductor layer 1050. Therefore, electrons injected into the first n-type nitride semiconductor layer 1050 are uniformly diffused and transported to the second n-type nitride semiconductor layer 1070. Further, the second metal layer 1060-2 functions as a part of the n-type electrode 1140.

A metal material among the materials of the first buffer layer 1030-1 can be used for the metal layer 1060. This allows an n-type nitride semiconductor film to be formed on the metal layer 1060 by heteroepitaxial growth from the metal layer 1060, and the crystallinity of the second n-type nitride semiconductor layer to be controlled. Titanium is preferably used for the metal layer 1060. Since titanium forms an ohmic contact with the n-type nitride semiconductor, the effective resistivity of the first n-type nitride semiconductor layer 1050 is likely to decrease. Further, since titanium has a high reflectivity, the light emitted from the light emitting layer 1080 is reflected and the light extraction efficiency of the light emitting device 1 is improved when the light emitted from the light emitting element 1000 is extracted from the upper surface.

Although the thickness of the metal layer 1060 is not particularly limited to a specific value, the thickness of the metal layer 1060 is preferably greater than or equal to 100 nm and less than or equal to 700 nm.

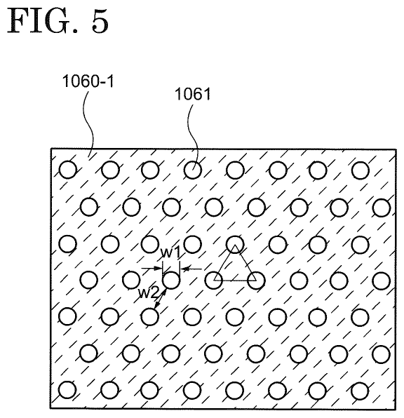

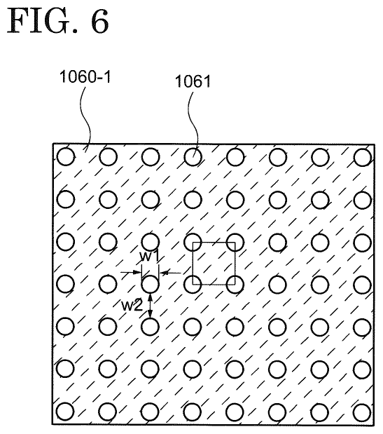

The metal layer 1060 has a predetermined pattern shape. Here, the pattern shape of the metal layer 1060 is described with reference to FIGS. 5 and 6.

Each of FIGS. 5 and 6 is a schematic plan view illustrating the pattern shape of the metal layer 1060 in the light emitting element 1000 of the light emitting device 1 according to an embodiment of the present invention. Specifically, each of FIGS. 5 and 6 is a plan view showing the pattern shape of the metal layer 1060 in a region overlapping the light emitting layer 1080.

The metal layer 1060 shown in FIG. 5 has a pattern shape in which a plurality of opening portions 1061 are arranged in a regular triangular lattice. The metal layer 1060 shown in FIG. 6 has a pattern shape in which a plurality of opening portions 1061 are arranged in a square lattice. In the opening portion 1061, the first n-type nitride semiconductor layer 1050 is exposed. The opening portion 1061 has a circular planar shape, and an opening diameter (diameter) w1 is greater than or equal to 1 μm and less than or equal to 200 μm. Further, the distance w2 between two adjacent opening portions 1061 is greater than or equal to 5 μm and less than or equal to 1000 μm.

Although the arrangement of the plurality of opening portions 1061 is not limited to a regular triangular lattice or a square lattice, the arrangement is preferably a periodic arrangement. When the plurality of opening portions 1061 is periodically arranged, a nitride semiconductor film is uniformly formed by homoepitaxial growth from the first n-type nitride semiconductor layer 1050. The planar shape of the opening portion 1061 is not limited to a circular shape. The planar shape of the opening portion 1061 may be a triangular shape, a rectangular shape, a hexagonal shape, or the like. When the planar shape of the opening portion 1061 is other than a circular shape, the opening diameter w1 is defined as the diameter of a circumscribed circle. When the planar shape of the opening portion 1061 is a hexagonal shape, it is preferable that each side of the hexagonal shape of the opening portion 1061 is formed to correspond to the m-plane of the n-type nitride semiconductor included in the first n-type nitride semiconductor layer 1050.

### [3-10. Configuration of P-Type Electrode 1130 and N-Type Electrode 1140]

The p-type electrode 1130 is formed on the p-type nitride semiconductor layer 1090. Further, the n-type electrode 1140 is formed on the first n-type nitride semiconductor layer 1050.

The p-type electrode 1130 can inject holes into the p-type nitride semiconductor layer 1090. The p-type electrode 1130 includes the transparent electrode layer 1110 and the first conductive layer 1120-1. The transparent electrode layer 1110 of the p-type electrode 1130 is in contact with the p-type nitride semiconductor layer 1090. a transparent conductive oxide film containing indium tin oxide (ITO), indium zinc oxide (IZO), zinc oxide (ZnO), or the like can be used for the transparent electrode layer 1110.

The n-type electrode 1140 can inject electrons into the first n-type nitride semiconductor layer 1050. The n-type electrode 1140 includes the second metal layer 1060-2 and the second conductive layer 1120-2. The second metal layer 1060-2 of the n-type electrode 1140 is in contact with the first n-type nitride semiconductor layer 1050.

Although the first conductive layer 1120-1 and the second conductive layer 1120-2 are preferably formed in the same layer, the first conductive layer 1120-1 and the second conductive layer 1120-2 are not limited thereto. The first conductive layer 1120-1 preferably has a lower resistivity than the transparent electrode layer 1110. The second conductive layer 1120-2 preferably has a lower resistivity than the second metal layer 1060-2. Specifically, each of the first conductive layer 1120-1 and the second conductive layer 1120-2 includes copper (Cu) and a barrier metal for preventing the diffusion of copper. Titanium (Ti), titanium nitride (TiN), tantalum (Ta), tantalum nitride (TaN), or the like can be used as the barrier metal. The barrier metal may be a single film or a laminated film. For example, a laminated film (TiN/Ti) of titanium and titanium nitride can be used as the barrier metal. In this case, the p-type electrode 1130 has a laminated structure of Cu/TiN/Ti. Further, the n-type electrode 1140 has a laminated structure of Cu/TIN/Ti/Ti.

The first conductive layer 1120-1, which has a lower resistivity than the transparent electrode layer 1110, is in contact with the transparent electrode layer 1110, thereby reducing the effective resistivity of the p-type electrode 1130. Therefore, the resistance between the p-type electrode 1130 and the p-type nitride semiconductor layer 1090 is reduced. Similarly, the second conductive layer 1120-2, which has a lower resistivity than the second metal layer 1060-2, is in contact with the second metal layer 1060-2, thereby reducing the effective resistivity of the n-type electrode 1140. Therefore, the resistance between the n-type electrode 1140 and the first n-type nitride semiconductor layer 1050 is reduced. Further, the first conductive layer 1120-1 and the second conductive layer 1120-2 can be used as wiring arranged in the display portion 10. Since the wiring using the first conductive layer 1120-1 and the second conductive layer 1120-2 has a low resistance, it is possible to suppress a voltage drop due to differences in the arrangement or distance of the wiring. Therefore, the variation among the plurality of light emitting elements 1000 in the display portion 10 can be suppressed.

In the light emitting device 1 according to the present invention, each of the plurality of light emitting elements 1000 included in the pixel of the light emitting device 1 includes the first metal layer 1060-1 in contact with the first n-type nitride semiconductor layer 1050, and as a result, the effective resistivity of the first n-type nitride semiconductor layer 1050 is reduced. Further, the p-type electrode 1130 and the n-type electrode 1140 include the first conductive layer 1120-1 and the second conductive layer 1120-2, each of which has a low resistivity. This reduces the resistance between the p-type electrode 1130 and the p-type nitride semiconductor layer 1090 and the resistance between the n-type electrode 1140 and the first n-type nitride semiconductor layer 1050. Further, the first conductive layer 1120-1 and the second conductive layer 1120-2 can be used as low-resistance wiring arranged in the display portion 10. In this way, since the voltage drop caused by the resistance in the display portion 10 is suppressed, the variation among the plurality of light emitting elements 1000 is suppressed in the light emitting device 1.

### [4. Configuration of Nitride Semiconductor Film Formation Apparatus 2]

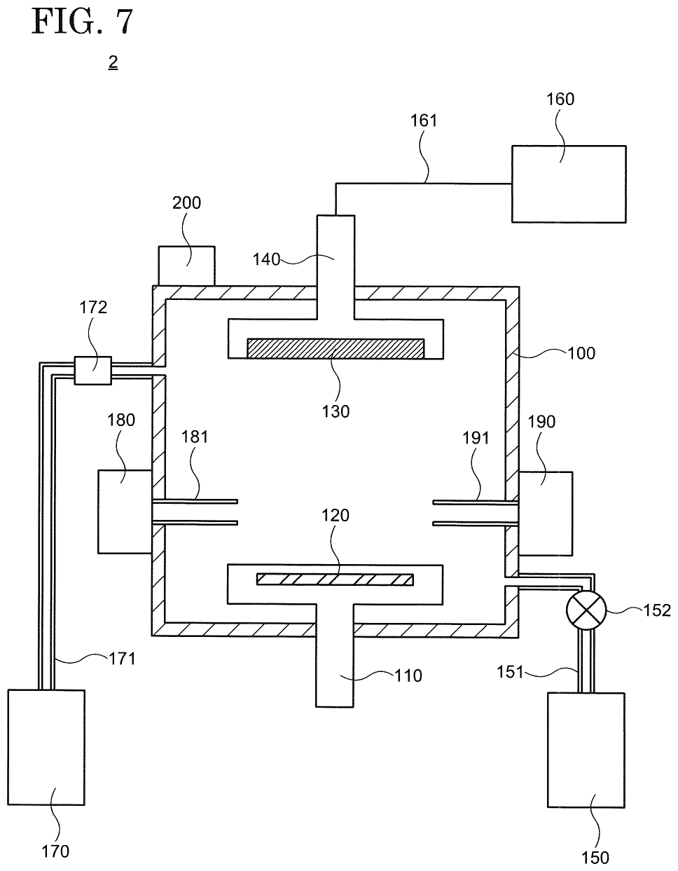

A film formation apparatus 2 capable of forming a nitride semiconductor film on a large-area substrate (substrate 1010) is described with reference to FIG. 7.

FIG. 7 is a schematic diagram showing a configuration of the film formation apparatus 2 for forming a nitride semiconductor film in the light emitting device 1 according to an embodiment of the present invention.

As shown in FIG. 7, the film formation apparatus 2 includes a vacuum chamber 100, a substrate support portion 110, a heating unit 120, a target 130, a target support portion 140, a pump 150, a sputtering power source 160, a sputtering gas supply unit 170, a first radical supply source 180, a second radical supply source 190, and a control unit 200.

The substrate support portion 110, the heating unit 120, the target 130, and the target support portion 140 are provided in the vacuum chamber 100. The substrate support portion 110 and the heating unit 120 are provided at a lower part in the vacuum chamber 100. The substrate 1010 is placed on the substrate support portion 110. The heating unit 120 is provided in the substrate support 110 and is capable of heating the substrate 1010 placed on the substrate support portion 110. The target 130 and the target support portion 140 are provided at an upper part in the vacuum chamber 100. The target 130 is supported by the target support portion 140 and is provided to face the substrate 1010 placed on the substrate support portion 110.

In addition, although FIG. 7 shows a configuration in which the substrate support portion 110 and the heating unit 120 are provided at the lower part in the vacuum chamber 100 and the target 130 and the target support portion 140 are provided at the upper part in the vacuum chamber 100, these positions may be reversed.

A predetermined nitride semiconductor according to the nitride semiconductor film formed over the substrate 1010 is used as the target 130. For example, when the nitride semiconductor film is a gallium nitride film, the target 130 contains gallium nitride. Further, when an n-type nitride semiconductor film or a p-type nitride semiconductor film is formed, a nitride semiconductor to which silicon (Si) or magnesium (Mg) is added can be used as the target 130. Nitrogen of the nitride semiconductor film formed on the substrate 1010 is supplied from the target 130 and the first radical supply source 180, while the group Ill element of the nitride semiconductor film is supplied only from the target 130. Therefore, it is preferable that the composition of the nitride semiconductor of the target 130 contains more of the group III element than nitrogen. Further, it is preferable that the target support portion 140 is an yttria-based material having corrosion resistance to chlorine, which is an etching gas (a second gas) described later.

The pump 150, the sputtering power source 160, the sputtering gas supply unit 170, the first radical supply source 180, and the second radical supply source 190 are provided outside the vacuum chamber 100.

The pump 150 is connected to the vacuum chamber 100 through a pipe 151. The pump 150 can exhaust gas from the vacuum chamber 100 through the pipe 151. That is, the inside of the vacuum chamber 100 can be evacuated by the pump 150 connected to the vacuum chamber 100. Further, the pressure in the vacuum chamber 100 can be kept constant by opening and closing a valve 152 connected to the pipe 151. For example, a turbo molecular pump or a cryopump can be used as the pump 150.

The sputtering power source 160 is electrically connected to the target 130 via wiring 161. The sputtering power source 160 can generate a direct current voltage (DC voltage) or an alternating current voltage (AC voltage) and apply the generated voltage to the target 130. The frequency of the AC voltage is 13.56 MHz. The sputtering power source 160 can also apply a bias voltage to the target 130 and further apply a DC voltage or an AC voltage.

The sputtering power source 160 may periodically change a voltage applied to the target 130. For example, a voltage is applied to the target 130 for a period of 50 usec to 10 msec, and then the application of the voltage to the target 130 may be stopped for a period of 2 usec to 10 msec. In the film formation apparatus 10 according to the present embodiment, a period in which a voltage is applied to the target 130 and a period in which the application of the voltage to the target 130 is stopped are repeated to form a gallium nitride film. In the following description, a state in which a voltage is applied to the target 130 may be referred to as an “on-state of the sputtering power source 160,” and a state in which a voltage is not applied to the target 130 may be referred to as an “off-state of the sputtering power source 160.”

The sputtering gas supply unit 170 is connected to the vacuum chamber 100 through a pipe 171. The sputtering gas supply unit 170 can supply a sputtering gas into the vacuum chamber 100 through the pipe 171. Further, the flow rate of the sputtering gas can be controlled by a mass flow controller 172 connected to the pipe 171. Argon (Ar) or krypton (Kr) can be used as the sputtering gas supplied from the sputtering gas supply unit 170.

The first radical supply source 180 is connected to a pipe 181 provided in the vacuum chamber 100, and can supply nitrogen radicals and hydrogen radicals into the vacuum chamber 100. The pipe 181 may be provided with one end facing the substrate support part 110. In this case, the nitrogen radicals and the hydrogen radicals can be irradiated from one end of the pipe 181 toward the substrate 1010 placed on the substrate support portion 110. Although details are described later, the first radical supply source 180 can generate the nitrogen radicals by turning a first gas containing nitrogen into a plasma.

The second radical supply source 190 is connected to a pipe 191 provided in the vacuum chamber 100, and can supply chlorine radicals into the vacuum chamber 100. The pipe 191 may be provided such that one end of the pipe 191 faces the substrate support portion 110. In this case, the chlorine radicals can be irradiated from one end of the pipe 191 toward the substrate 1010 placed on the substrate support portion 110. Although details are described later, the second radical supply source 190 can generate the chlorine radicals by turning a second gas containing chlorine into a plasma.

In addition, the first radical source 180 may be provided in the vacuum chamber 100 and generate the nitrogen radicals in the vacuum chamber 100. Similarly, the second radical source 190 may be provided in the vacuum chamber 100 and generate the chlorine radicals in the vacuum chamber 100.

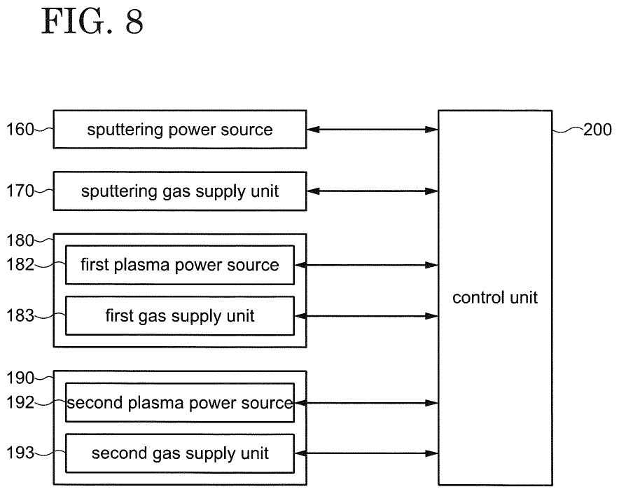

The control unit 200 can control the operation of the film formation apparatus 2 in forming the nitride semiconductor film. The control unit 200 is a computer that can perform arithmetic processing using data or information, and includes, for example, a central processing unit (CPU), a microprocessor (MPU), or a random access memory (RAM). Specifically, the control unit 200 executes a predetermined program to control the operation of the film formation apparatus 2. Here, the details of the control of the control unit 200 are described with reference to FIG. 8.

FIG. 8 is a block diagram showing connections of the control unit 200 of the film formation apparatus 2 that forms a nitride semiconductor film in the light emitting device 1 according to an embodiment of the present invention.

As shown in FIG. 8, the control unit 200 is connected to the sputtering power source 160 and the sputtering gas supply unit 170. Therefore, the control unit 200 can control the on- or off-state of the sputtering power source 160 and the start or stop of the supply of the sputtering gas to the vacuum chamber 100. In addition, although FIG. 2 shows a configuration in which the control unit 200 is connected to the sputtering gas supply unit 170, the control unit 200 may be connected to the mass flow controller 172 to control the start or stop of the supply of the sputtering gas by the mass flow controller 172.

Further, the control unit 200 is connected to a first plasma power source 182 and a first gas supply unit 183 included in the first radical supply source 180. Therefore, the control unit 200 can control the on- or off-state of the first plasma power source 182 and the start or stop of the supply of the first gas. The first plasma power source 182 turns the first gas supplied from the first gas supply unit 183 into a plasma. Therefore, when the control unit 200 starts the supply of the first gas and controls the first plasma power source 182 to be in the on-state, the radicals of the first gas are supplied from the first radical supply source 180 to the vacuum chamber 100. The first gas is a gas containing nitrogen and hydrogen, such as a nitrogen/hydrogen mixed gas (N₂/H₂ mixed gas) or ammonia gas (NH₃ gas). Therefore, nitrogen radicals and hydrogen radicals are supplied from the first radical supply source 180 to the vacuum chamber 100 as the radicals of the first gas. In addition, when the control unit 200 starts the supply of the first gas and controls the first plasma power source 182 to be in the off-state, the first gas may be supplied from the first radical supply source 180 to the vacuum chamber 100.

Further, the control unit 200 is connected to the second plasma power source 192 and the second gas supply unit 193 included in the second radical supply source 190. Therefore, the control unit 200 can control the on- or off-state of the second plasma power source 192 and the start or stop of the supply of the second gas. The second plasma power source 192 turns the second gas supplied from the second gas supply unit 193 into a plasma. Therefore, when the control unit 200 starts the supply of the second gas and controls the second plasma power source 192 to be in the on-state, the radicals of the second gas are supplied from the second radical supply source 190 to the vacuum chamber 100. The second gas is a gas containing chlorine, such as chlorine gas (Cl₂ gas) or boron trichloride gas (BCl₃ gas). Therefore, chlorine radicals are supplied from the second radical supply source 190 to the vacuum chamber 100 as the radicals of the second radicals. In addition, when the control unit 200 starts the supply of the second gas and controls the second plasma power source 192 to be in an off-state, the second gas may be supplied from the second radical supply source 190 to the vacuum chamber 100.

The control unit 200 may control the pump 150 so that a predetermined pressure is maintained in the vacuum chamber 100. Further, the control unit 200 may control the heating unit 120 so that the substrate 1010 placed on the substrate support portion 110 is heated at a predetermined temperature.

### [5. Method for Forming Nitride Semiconductor Film Using Film Formation Apparatus 2]

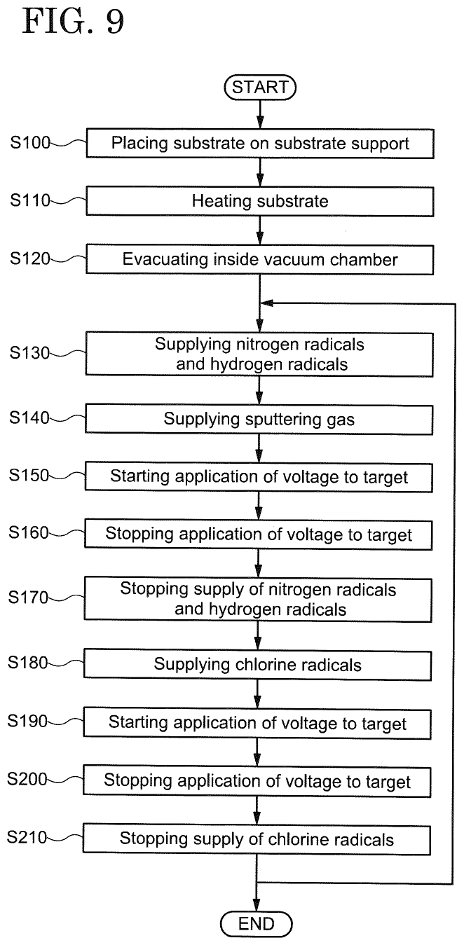

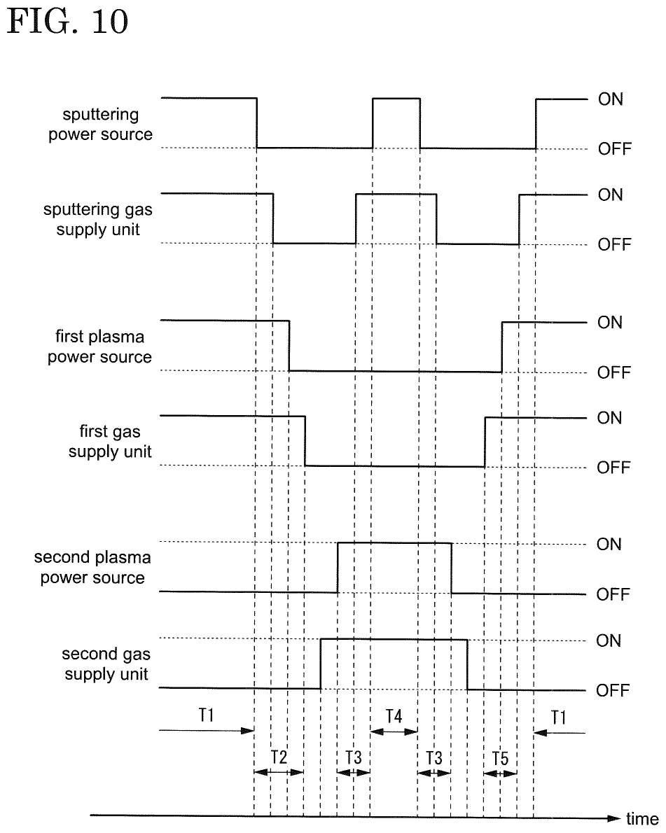

Although the nitride semiconductor film (or the n-type nitride semiconductor film or the p-type nitride semiconductor film) included in the light emitting element 1000 of the light emitting device 1 according to the present invention is not limited to being formed using the film formation apparatus 2, the nitride semiconductor film having high crystallinity can be formed even at a low substrate temperature of 400° C. to 600° C. by using the film formation apparatus 2. Therefore, a method for forming a nitride semiconductor film using the film formation apparatus 2 is described with reference to FIGS. 9 and 10.

FIG. 9 is a flow chart showing a method for forming a nitride semiconductor film using the film formation apparatus 2 in a manufacturing method for the light emitting device 1 according to an embodiment of the present invention. In the method for forming a nitride semiconductor film shown in FIG. 9, steps S100 to S210 are sequentially performed. Although steps S100 to S210 are described in order below, the description is given assuming that the nitride semiconductor film is a gallium nitride film for convenience.

In step S100, the substrate 1010 is placed on the substrate support 110 so as to face the target 130.

In step S110, the substrate 1010 is heated at a predetermined temperature by the heating unit 120. For example, the predetermined temperature is greater than or equal to 400° C. and less than or equal to 600° C.

In step S120, the pump 150 evacuates the gas inside the vacuum chamber 100 to a predetermined degree of vacuum or less. Although the predetermined degree of vacuum is, for example, 10⁻⁶ Pa, the predetermined degree of vacuum is not limited thereto.

In step S130, the first radical supply source 180 is controlled to supply nitrogen radicals and hydrogen radicals from the first radical supply source 180 to the vacuum chamber 100.

In step S140, the sputtering gas supply unit 170 is controlled to supply the sputtering gas from the sputtering gas supply unit 170 to the vacuum chamber 100. The flow rate of the sputtering gas is adjusted by the mass flow controller 172 so that the pressure inside the vacuum chamber 100 becomes a predetermined pressure. For example, the predetermined pressure is greater than or equal to 0.1 Pa and less than or equal to 10 Pa.

In step S150, the sputtering power supply 160 is controlled to start applying a predetermined voltage to the target 130 so that the target 130 becomes a cathode relative to the substrate (the sputtering power supply 160 is turned on). This causes the sputtering gas supplied to the vacuum chamber 100 to become a plasma, generating positive ions and electrons of the sputtering gas. The ions of the sputtering gas are accelerated by the potential difference between the substrate and the target 130 and collide with the target 130. As a result, sputtered gallium and gallium positive ions are released from the target 130.

In step S150, nitrogen radicals are supplied from the first radical supply source 180 to the vacuum chamber 100. Therefore, the gallium released from the target 130 recombines and reacts with the nitrogen radicals to generate gallium nitride. The generated gallium nitride is deposited on the substrate 1010 to form a gallium nitride film.

Further, in step S150, gallium nitride is also generated by another recombination reaction. Nitrogen has a large electronegativity and easily attracts electrons. Therefore, the nitrogen radicals react with electrons in the vacuum chamber 100 to generate nitrogen anions. The generated nitrogen anion undergoes a recombination reaction with a gallium cation present in the vicinity of the substrate 1010 to generate gallium nitride. The generated gallium nitride is deposited on the substrate 1010 to form a gallium nitride film. Since the recombination reaction of a cation and an anion is a reaction that releases a large amount of energy, a gallium nitride film can be formed on the substrate 1010 even when the temperature of the substrate 1010 is low.

However, oxygen may remain in the vacuum chamber 100. In this case, a gallium cation reacts with the residual oxygen in the vacuum chamber 100 to generate gallium oxide. When gallium oxide is generated, the growth of the gallium nitride film is inhibited, so it is preferable that the residual oxygen in the vacuum chamber 100 is reduced as much as possible. In step S150, not only nitrogen radicals but also hydrogen radicals are supplied to the vacuum chamber 100. The hydrogen radical reacts with the residual oxygen to generate water (water vapor). The generated water vapor is exhausted from the vacuum chamber 100 by the pump 150. That is, since the residual oxygen in the vacuum chamber 100 is reduced in the film formation apparatus 2, the generation of gallium oxide is suppressed, and as a result, the gallium nitride film formed on the substrate 1010 is a high-quality film.

As described above, hydrogen radicals have the effect of removing residual oxygen that inhibits the generation of gallium nitride. Further, the hydrogen radical may react with a gallium cation to generate a gallium hydride cation. The gallium hydride cation is highly reactive and easily reacts with a nitrogen anion to generate gallium nitride. Therefore, hydrogen radicals also have the effect of promoting the generation of gallium nitride.

In step S160, the sputtering power supply 160 is controlled to stop applying voltage to the target 130 (the sputtering power supply 160 is turned off). Although this causes the plasma to disappear, gallium nitride can be generated even in this state in the film formation apparatus 2. Specifically, in step S160, gallium nitride can be generated by utilizing the metastable state of the sputtering gas (rare gas). Here, the details of the generation of gallium nitride in step S160 are described.

It is known that a rare gas atom in a metastable state with a long lifetime exists in the plasma of the rare gas. For example, metastable energies of an argon atom and a krypton atom are 11.61 eV and 9.91 eV, respectively. Such metastable argon atoms or krypton atoms are generated in the plasma of sputtering, and can exist even after the plasma disappears due to their long lifetime. That is, the metastable argon atoms or krypton atoms can exist even after the application of the voltage to the target 130 is stopped.

After the application of the voltage to the target 130 is stopped, not only the nitrogen radicals but also nitrogen molecules are present in the vacuum chamber 100. The dissociation energy from nitrogen molecules to nitrogen atoms due to the collision of electrons is 9.756 eV, which is close to the metastable energy of the argon atom or krypton atom. Therefore, when a nitrogen molecule collides with the argon atom or krypton atom in a metastable state, a dissociation reaction of the nitrogen molecule occurs, and nitrogen radicals are generated. That is, even after the application of the voltage to the target 130 is stopped, nitrogen radicals are generated by the argon atom or krypton atom in the metastable state. As described above, since the electronegativity of nitrogen is large, the nitrogen radical reacts with the electron in the vacuum chamber 100 to generate a nitrogen anion. Further, in step S160, the nitrogen radicals are supplied from the first radical supply source 180 to the vacuum chamber 100. The supplied nitrogen radical reacts with the electron in the vacuum chamber 100 to generate a nitrogen anion. The generated nitrogen anion recombines with a gallium cation present near the substrate to generate gallium nitride, which is deposited on the substrate to form a gallium nitride film.

Therefore, in step S160, by utilizing not only the nitrogen radicals supplied from the first radical supply source 180 but also the metastable argon atoms or krypton atoms, gallium nitride can be generated efficiently.

In step S170, the first radical supply source 180 is controlled to stop the supply of nitrogen radicals and hydrogen radicals to the vacuum chamber 100.

In step S180, the second radical supply source 190 is controlled, and chlorine radicals are supplied from the second radical supply source 190 to the vacuum chamber 100. The gallium nitride film formed in steps S150 and S160 includes not only crystalline regions but also amorphous regions. Therefore, in step S180, the chlorine radicals are used to etch the amorphous regions of the gallium nitride film. This etching can improve the crystallinity of the gallium nitride film formed on the substrate. In addition, the amorphous regions have weaker bonds between gallium and nitrogen than the crystalline regions. Therefore, selective etching of the amorphous regions is possible. Further, the boiling point of gallium chloride generated by etching at room temperature is about 200° C. Therefore, gallium chloride is a gas in the vicinity of the substrate heated at a temperature higher than or equal to 400° C., and gallium nitride is not deposited on the substrate.

In step S190, the sputtering power supply 160 is controlled to start applying a predetermined voltage to the target 130 so that the target 130 becomes a cathode relative to the substrate (the sputtering power supply 160 is turned on). This causes the chlorine radicals supplied to the vacuum chamber 100 to become a plasma. Chlorine has a large electronegativity and easily attracts an electron. Therefore, the chlorine radical reacts with the electron in the plasma to generate a chlorine anion. Therefore, in step S190, the amorphous regions of the gallium nitride film can be etched using not only the chlorine radicals but also the chlorine anions. Therefore, the amorphous regions of the gallium nitride film can be efficiently etched.

In step S200, the sputtering power supply 160 is controlled to stop applying a voltage to the target 130 (the sputtering power supply 160 is turned off).

In step S210, the second radical supply source 190 is controlled to stop the supply of chlorine radicals to the vacuum chamber 100.

In the gallium nitride film deposition method using the deposition apparatus 2, by repeating steps S130 to S210, a high-quality gallium nitride film with improved crystallinity can be deposited on the substrate 1010. Here, the details of the timing of control by the control unit 200 are described with reference to FIG. 10.

FIG. 10 is a sequence diagram showing the timing of control by the control unit 200 of the film formation apparatus 2 in the manufacturing method of the light emitting device 1 according to an embodiment of the present invention. In addition, the sequence diagram shown in FIG. 10 is an example, and the control by the control unit 200 is not limited thereto.

FIG. 10 shows the first period T1 to the fifth period T5 related to the deposition process of the gallium nitride film. The sputtering power supply 160 is in an on state in the first period T1 and the fourth period T4, and the sputtering power supply 160 is in an off state in the second period T2, the third period T3, and the fifth period T5. The period during which the sputtering power supply 160 is in an on state (the on period of the sputtering power supply 160) is greater than or equal to 50 μsec and less than or equal to 10 msec, for example. It is preferable that the on period of the sputtering power supply 160 is greater than or equal to 50 μsec in order to stabilize the plasma. Further, the period during which the sputtering power supply 160 is in an off state (the off period of the sputtering power supply 160) is greater than or equal to 2 μsec and less than or equal to 10 msec, for example. It is preferable that the off period of the sputtering power supply 160 is greater than or equal to the life of the sputtering gas in a metastable state.

### (First Period T1)

The first period T1 is a period during which the sputtering power supply 160 is on. In the first period T1, a sputtering gas is supplied from the sputtering gas supply unit 170 to the vacuum chamber 100. Further, the first gas is supplied from the first gas supply unit 183, and the first plasma power supply 182 is on. That is, in the first radical supply source 180, nitrogen radicals and hydrogen radicals are generated, and the generated nitrogen radicals and hydrogen radicals are supplied to the vacuum chamber 100. On the other hand, the supply of the second gas from the second gas supply unit 193 is stopped, and the second plasma power supply 192 is off. That is, in the second radical supply source 190, chlorine radicals are not generated, and chlorine radicals are not supplied to the vacuum chamber 100.

In the first period T1, the above-described step S150 is performed. That is, in the first period T1, the sputtering gas supplied to the vacuum chamber 100 is turned into a plasma, and positive ions and electrons of the sputtering gas are generated. The positive ions of the sputtering gas collide with the target 130, and sputtered gallium and gallium positive ions are released from the target 130. The gallium released from the target 130 recombines and reacts with the nitrogen radical to generate gallium nitride. Further, the nitrogen radical supplied to the vacuum chamber 100 reacts with the electron to generate a nitrogen negative ion. The generated nitrogen negative ion recombines and reacts with the gallium positive ion present in the vicinity of the substrate to generate gallium nitride. The generated gallium nitride is deposited on the substrate 1010, and a gallium nitride film is formed.

### (Second Period T2)

The second period T2 is included in the off period of the sputtering power supply 160. In the second period T2, the supply of the sputtering gas from the sputtering gas supply unit 170 to the vacuum chamber 100 is stopped. Further, the first plasma power supply 182 is turned off while the first gas is supplied from the first gas supply unit 183. Therefore, not only nitrogen radicals and hydrogen radicals but also the first gas containing nitrogen are supplied from the first radical supply source 180 to the vacuum chamber 100. Further, the supply of the second gas from the second gas supply unit 193 is stopped, and the second plasma power supply 192 is in the off state. That is, in the second radical supply source 190, chlorine radicals are not generated, and chlorine radicals are not supplied from the second radical supply source 190 to the vacuum chamber 100.

In the second period T2, the above-described step S160 is performed. That is, in the second period T2, gallium nitride is generated by a recombination reaction between the nitrogen anion and the gallium cation using the metastable sputtering gas. The generated gallium nitride is deposited on a substrate to form a gallium nitride film.

As described above, when the gallium nitride film is formed not only in the first period T1 but also in the second period T2, the film formation speed of the gallium nitride film can be improved.

### (Third Period T3)

The third period T3 is included in the off period of the sputtering power supply 160. In the third period T3, the second gas is supplied from the second gas supply unit 193, and the second plasma power supply 192 is in the on state. That is, in the second radical supply source 190, chlorine radicals are generated, and the generated chlorine radicals are supplied to the vacuum chamber 100. Further, while the sputtering power supply 160 maintains the off state, the supply of the sputtering gas from the sputtering gas supply unit 170 to the vacuum chamber 100 is started or stopped. In addition, the supply of the first gas from the first gas supply unit 183 is stopped, and the first plasma power supply 182 is in the off state. That is, in the first radical supply source 180, nitrogen radicals and hydrogen radicals are not generated, and nitrogen radicals and hydrogen radicals are not supplied from the first radical supply source 180 to the vacuum chamber 100.

In the third period T3, the above-described step S180 is performed. That is, in the third period T3, etching of the amorphous regions of the gallium nitride film is performed using chlorine radicals.

### (Fourth Period T4)

The fourth period T4 is a period during which the sputtering power supply 160 is on. In the fourth period T4, the sputtering gas is supplied from the sputtering gas supply unit 170 to the vacuum chamber 100. Further, the second gas is supplied from the second gas supply unit 193, and the second plasma power supply 192 is in an on state. That is, in the second radical supply source 190, chlorine radicals are generated, and the generated chlorine radicals are supplied to the vacuum chamber 100. Furthermore, the supply of the first gas from the first gas supply unit 183 is stopped, and the first plasma power supply 182 is in an off state. That is, in the first radical supply source 180, nitrogen radicals and hydrogen radicals are not generated, and nitrogen radicals and hydrogen radicals are not supplied from the first radical supply source 180 to the vacuum chamber 100.

In the fourth period T4, the above-described step S190 is performed. That is, in the fourth period T4, etching of the amorphous regions of the gallium nitride film is performed using chlorine radicals and chlorine anions.

As described above, when the amorphous regions of the gallium nitride film are etched not only in the third period T3 but also in the fourth period T4, the crystallinity of the gallium nitride film can be improved.

In addition, the length of the fourth period T4 may be the same as or different from the length of the first period T1.

### (Fifth Period T5)

The fifth period is included in the off period of the sputtering power supply 160. In the fifth period T5, the sputtering gas supply unit 170 starts supplying the sputtering gas to the vacuum chamber 100. Further, the first plasma power supply 182 is turned on while the first gas is being supplied from the first gas supply unit 183. Therefore, nitrogen radicals and hydrogen radicals are supplied from the first radical supply source 180 to the vacuum chamber 100. Furthermore, the supply of the second gas from the second gas supply unit 193 is stopped, and the second plasma power supply 192 is in the off state. That is, in the second radical supply source 190, chlorine radicals are not generated, and chlorine radicals are not supplied from the second radical supply source 190 to the vacuum chamber 100.

In the fifth period T5, the hydrogen radical supplied to the vacuum chamber 100 reacts with chlorine in the vacuum chamber 100 or in the gallium nitride film to generate hydrogen chloride. Since the generated hydrogen chloride is exhausted from the vacuum chamber 100 by a pump, the residual chlorine in the vacuum chamber 100 or in the gallium nitride film is reduced. That is, the hydrogen radicals in the fifth period T5 have the effect of removing chlorine, which is an impurity in the gallium nitride film, and reducing the impurities in the gallium nitride film. Therefore, the gallium nitride film becomes a high-quality film with a low impurity concentration.

According to the method for forming a gallium nitride film using the film formation apparatus 2, the first period T1 to the fifth period T5 are repeated to repeat the process of forming the gallium nitride film, the process of etching the amorphous regions, and the process of reducing impurities. By performing these processes, the gallium nitride film formed on the substrate 1010 becomes a high-quality film with high crystallinity.

In addition, although the method for forming a gallium nitride film is described as an example of a method for forming a nitride semiconductor film, the above-described method for forming a nitride semiconductor film can also be applied to the formation of nitride semiconductor films other than a gallium nitride film.

### [6. Manufacturing Method of Light Emitting Device 1]

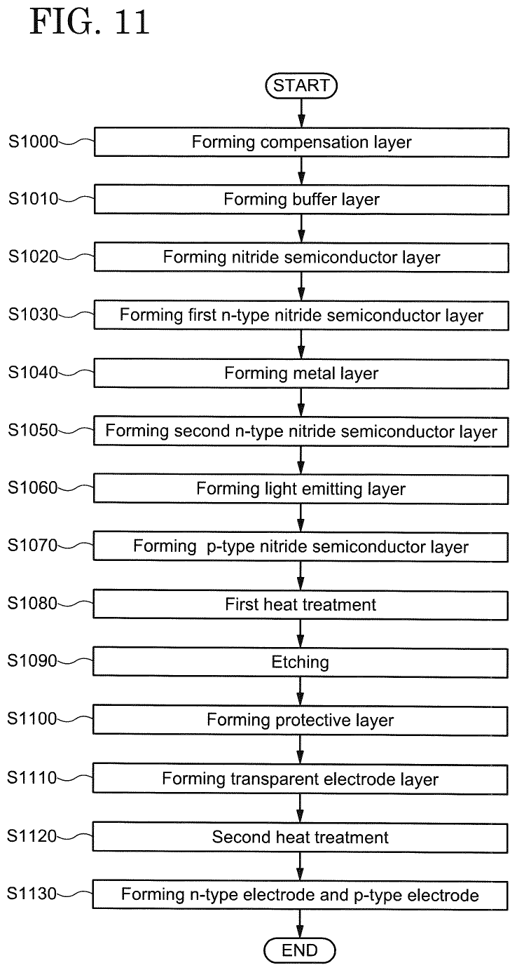

A method for manufacturing the light emitting device 1, in particular, the light emitting element 1000 included in the light emitting device 1, is described with reference to FIGS. 11 to 23.

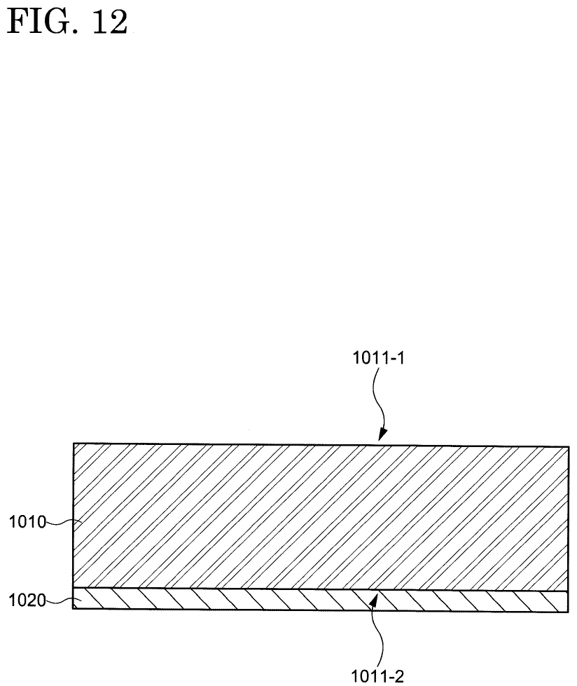

FIG. 11 is a flowchart showing a method for manufacturing the light emitting element 1000 of the light emitting device 1 according to an embodiment of the present invention. Further, FIGS. 12 to 23 are schematic cross-sectional views showing a method for manufacturing the light emitting element 1000 of the light emitting device 1 according to an embodiment of the present invention.

As shown in FIG. 11, the method for manufacturing the light emitting element 1000 includes steps S1000 to S1130. Steps S1000 to S1130 are described below in order with reference to FIGS. 12 to 23.

In step S1000, the compensation layer 1020 is formed on the second surface 1011-2 of the substrate 1010 (see FIG. 12). Specifically, an aluminum nitride film is formed on the second surface 1011-2 of the substrate 1010 by sputtering, thereby forming the compensation layer 1020.

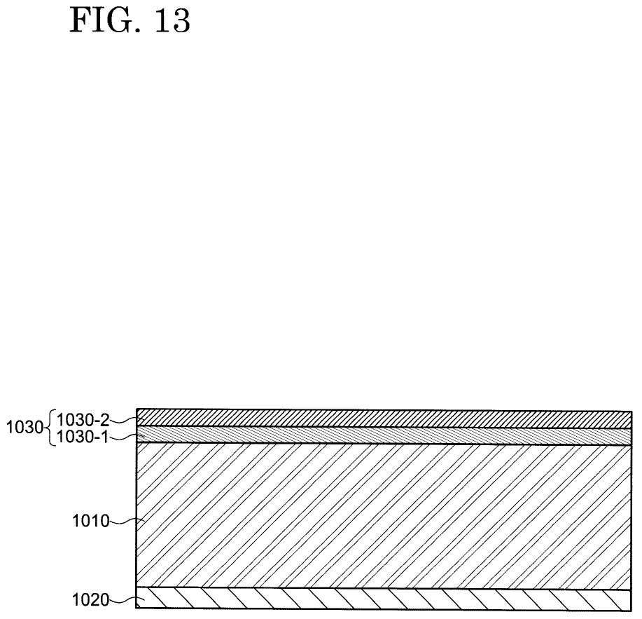

In step S1010, the buffer layer 1030 is formed on the first surface 1011-1 of the substrate 1010 (see FIG. 13). Specifically, the first buffer layer 1030-1 is formed on the first surface 1011-1 of the substrate 1010. Next, the second buffer layer 1030-2 is formed on the first buffer layer 1030-1. For example, a titanium film is formed as the first buffer layer 1030-1, and an aluminum nitride film is formed as the second buffer layer 1030-2 by sputtering. As a result, the buffer layer 1030 including the first buffer layer 1030-1 and the second buffer layer 1030-2 is formed.

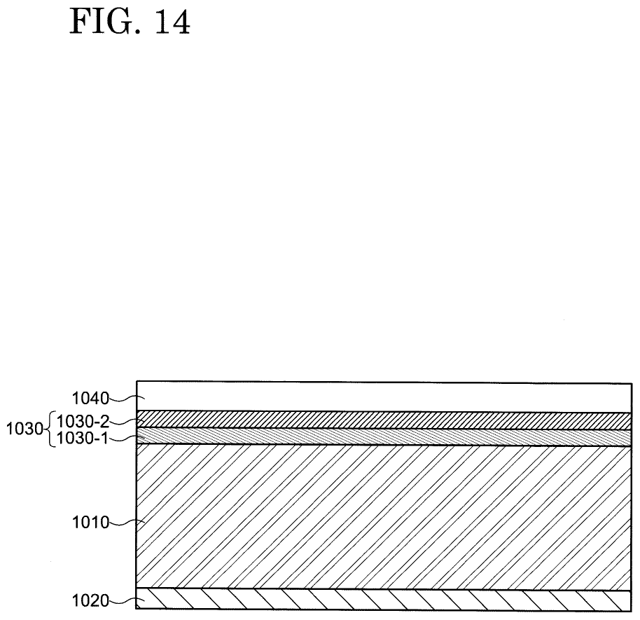

In step S1020, the nitride semiconductor layer 1040 is formed on the buffer layer 1030 (see FIG. 14). Specifically, a gallium nitride film is formed on the buffer layer 1030 by sputtering using the film formation apparatus 2 to form the nitride semiconductor layer 1040. Since the nitride semiconductor layer 1040 is formed on the buffer layer 1030, the crystal orientation is controlled and the nitride semiconductor layer 1040 has high crystallinity.

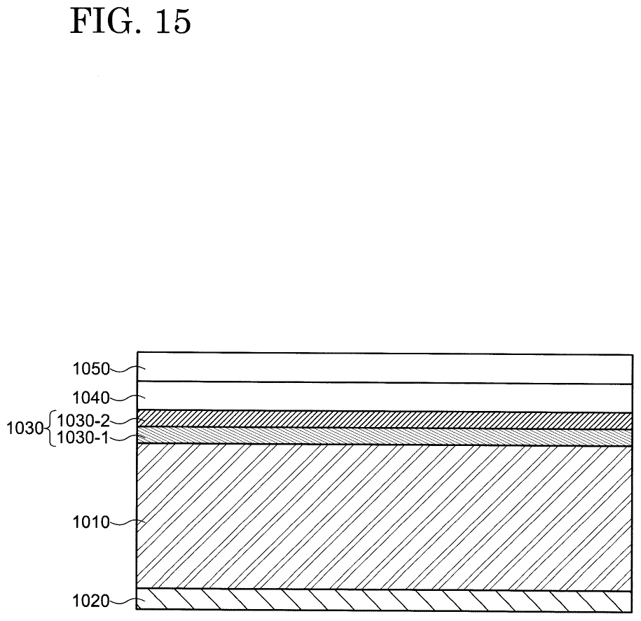

In step S1030, the first n-type nitride semiconductor layer 1050 is formed on the nitride semiconductor layer 1040 (see FIG. 15). Specifically, a gallium nitride film doped with silicon is formed on the nitride semiconductor layer 1040 by sputtering using the film formation apparatus 2 to form the first n-type nitride semiconductor layer 1050. Since the first n-type nitride semiconductor layer 1050 is formed on the nitride semiconductor layer 1040 with controlled crystal orientation, the first n-type nitride semiconductor layer 1050 also has high crystallinity.

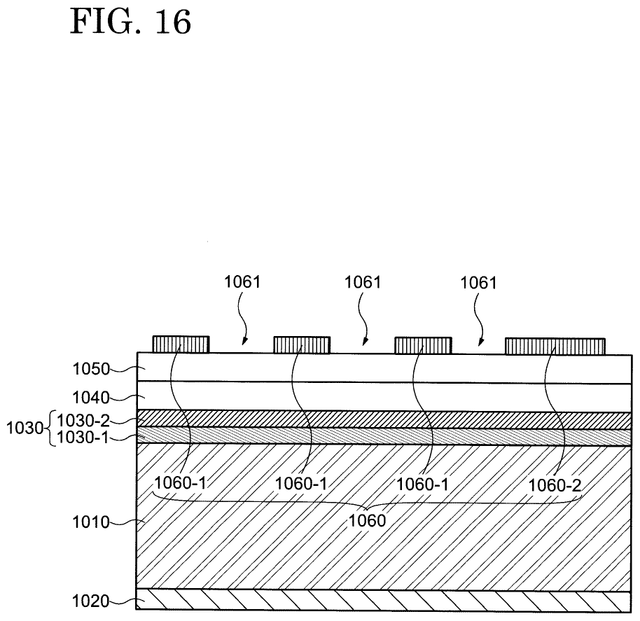

In step S1040, the metal layer 1060 is formed on the first n-type nitride semiconductor layer 1050 (see FIG. 16). Specifically, after forming a titanium film by sputtering, the titanium film is patterned using photolithography to have a predetermined pattern shape (for example, a pattern shape including a plurality of opening portions 1061). As a result, the metal layer 1060 including the first metal layer 1060-1 and the second metal layer 1060-2 is formed. In addition, the first n-type nitride semiconductor layer 1050 is exposed in the plurality of opening portions 1061.

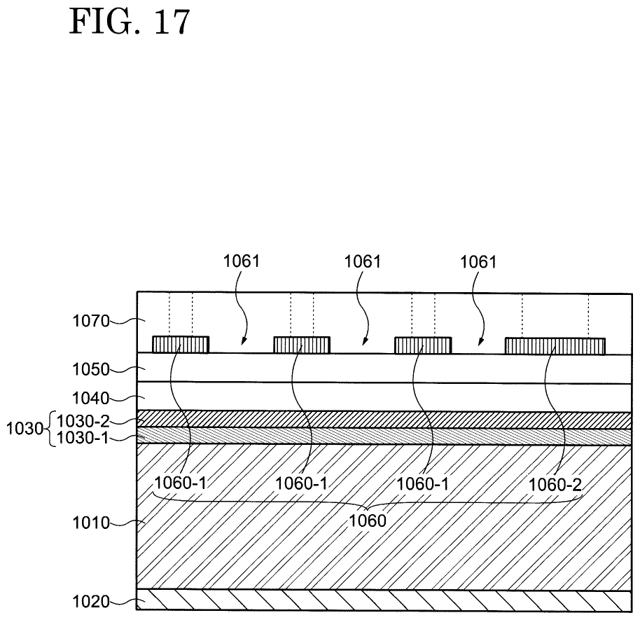

In step S1050, the second n-type nitride semiconductor layer 1070 is formed on the metal layer 1060 and the first n-type nitride semiconductor layer 1050 exposed through the opening portions 1061 (see FIG. 17). Specifically, a gallium nitride film doped with silicon is formed on the metal layer 1060 and the first n-type nitride semiconductor layer 1050 by sputtering using the film formation apparatus 2 to form the second n-type nitride semiconductor layer 1070. The first n-type nitride semiconductor layer 1050 and the second n-type nitride semiconductor layer 1070 are the same gallium nitride film (more specifically, a gallium nitride film doped with silicon). Therefore, a gallium nitride film is formed by homoepitaxial growth on the first n-type nitride semiconductor layer 1050. On the other hand, a gallium nitride film is formed by heteroepitaxial growth on the metal layer 1060. The gallium nitride film grown by homoepitaxial growth has better crystallinity than the gallium nitride film grown by heteroepitaxial growth. That is, the gallium nitride film grown by heteroepitaxial growth contains more amorphous regions than the gallium nitride film grown by homoepitaxial growth. When the film formation apparatus 2 is used, the amorphous regions in the gallium nitride film are etched as described above. Therefore, the crystal growth of the gallium nitride film on the first n-type nitride semiconductor layer 1050 is promoted more than that of the gallium nitride film on the metal layer 1060, and as a result, the gallium nitride crystal-grown from the first n-type nitride semiconductor layer 1050 crystal-grows laterally on the metal layer 1060 (see the dotted line in FIG. 17). Therefore, the second n-type nitride semiconductor layer 1070 also has high crystallinity.

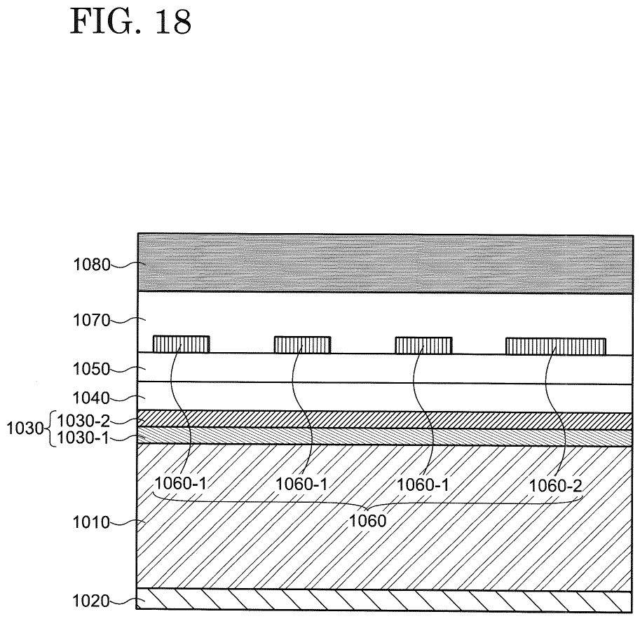

In step S1060, the light emitting layer 1080 is formed on the second n-type nitride semiconductor layer 1070 (see FIG. 18). Specifically, a gallium nitride film and an indium gallium nitride film are alternately formed on the second n-type nitride semiconductor layer 1070 by sputtering using the film formation apparatus 2 to form the light emitting layer 1080 in which the gallium nitride film and the indium gallium nitride film are laminated. Since the light emitting layer 1080 is formed on the second n-type nitride semiconductor layer 1070 having high crystallinity, the light emitting layer 1080 also has high crystallinity.

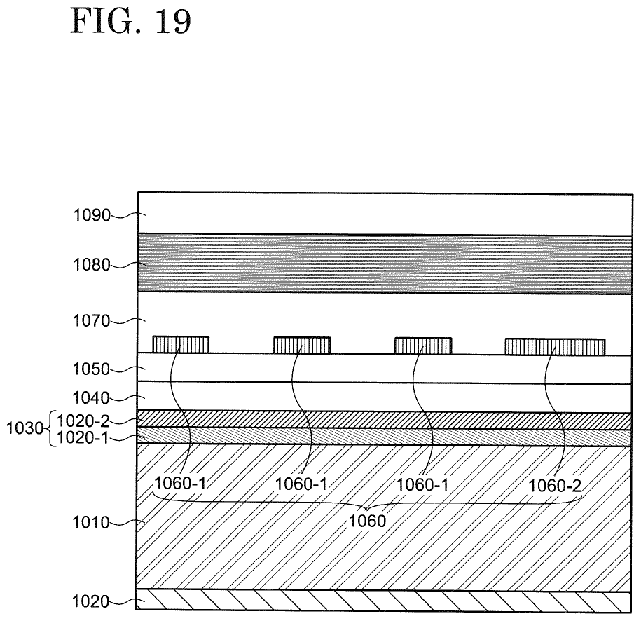

In step S1070, the p-type nitride semiconductor layer 1090 is formed on the light emitting layer 1080 (see FIG. 19). Specifically, a gallium nitride film doped with magnesium is formed on the light emitting layer 1080 by sputtering using the film formation apparatus 2, thereby forming the p-type nitride semiconductor layer 1090. Since the p-type nitride semiconductor layer 1090 is formed on the light emitting layer 1080 having high crystallinity, the p-type nitride semiconductor layer 1090 also has high crystallinity.

In step S1080, a first heat treatment is performed. The first heat treatment is a heat treatment for activating the p-type nitride semiconductor layer 1090. The first heat treatment improves the electrical conductivity of the p-type nitride semiconductor layer 1090.

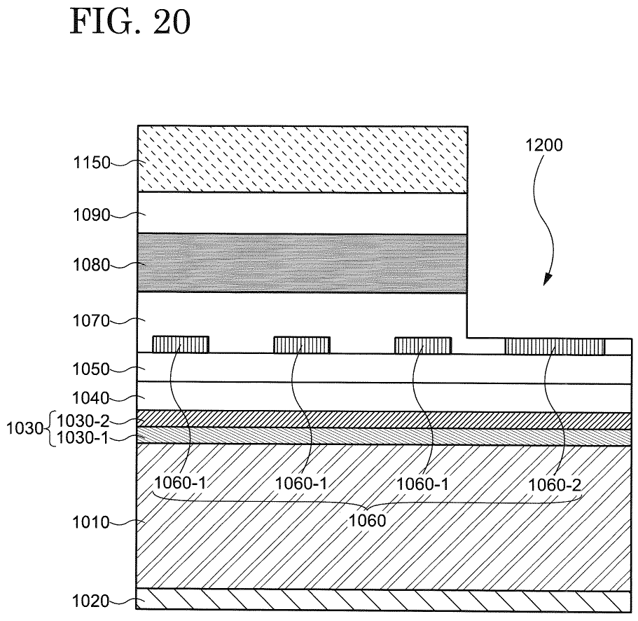

In step S1090, a predetermined resist pattern is formed on the p-type nitride semiconductor layer 1090 by photolithography, and the p-type nitride semiconductor layer 1090, the light emitting layer 1080, and the second n-type nitride semiconductor layer 1070 are etched so as to expose the second metal layer 1060-2. As a result, a recess 1200 is formed in which the second metal layer 1060-2 is exposed (see FIG. 20).

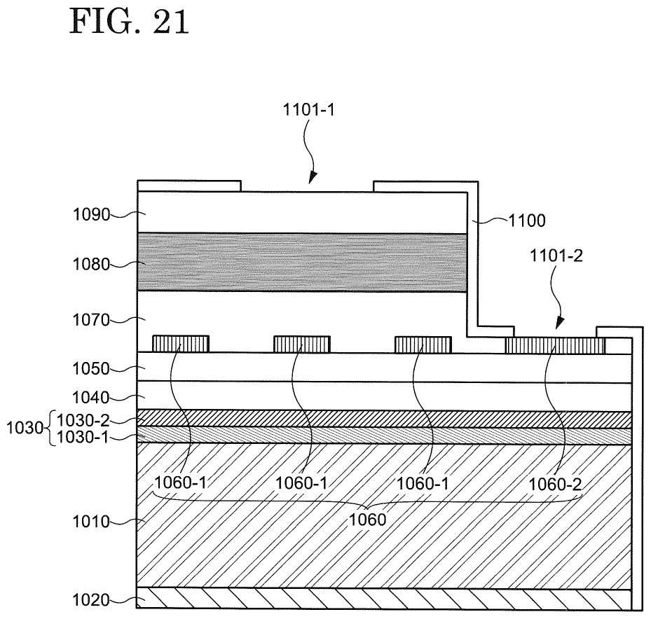

In step S1100, the protective layer 1100 is formed on the p-type nitride semiconductor layer 1090 and the exposed second metal layer 1060-2 (see FIG. 21). Specifically, after a silicon oxide film is formed by CVD, the silicon oxide film is patterned using photolithography to have a predetermined pattern shape (for example, a pattern shape including a first opening portion 1101-1 and a second opening portion 1101-2). As a result, the protective layer 1100 including the first opening portion 1101-1 and the second opening portion 1101-2 in which the p-type nitride semiconductor layer 1090 and the second metal layer 1060-2 are exposed, respectively, is formed.

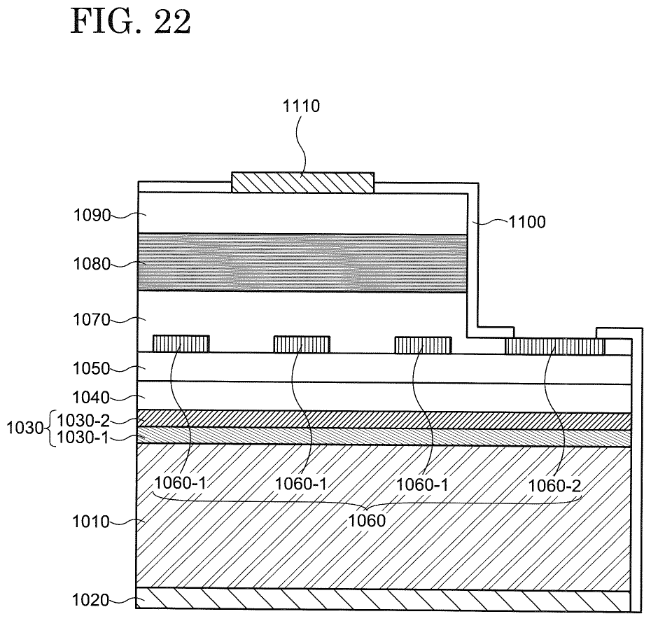

In step S1110, the transparent electrode layer 1110 is formed on the p-type nitride semiconductor layer 1090 exposed through the first opening 1101-1 (see FIG. 22). Specifically, an indium tin oxide film is formed by sputtering, and then the indium tin oxide film is patterned into a predetermined pattern shape (for example, a pattern shape in which the first opening portion 1101-1 is covered) using photolithography. In this way, the transparent electrode layer 1110 in contact with the p-type nitride semiconductor layer 1090 through the first opening 1101-1 is formed.

In step S1120, a second heat treatment is performed to reduce the resistance between the transparent electrode layer 1110 and the p-type nitride semiconductor layer 1090.

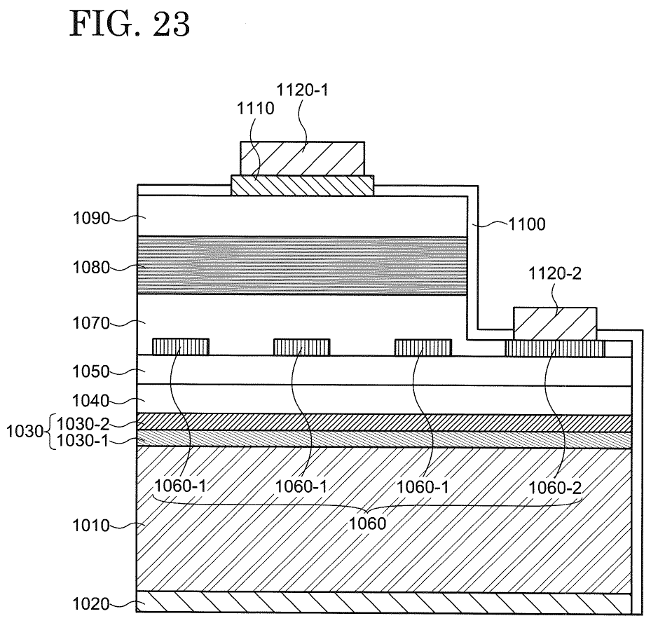

In step S1130, the first conductive layer 1120-1 and the second conductive layer 1120-2 are formed on the transparent electrode layer 1110 and the second metal layer 1060-2, respectively (see FIG. 23). Specifically, a Cu/TiN/Ti laminated film is formed by sputtering, and then the laminated film is patterned into a predetermined pattern shape by photolithography. As a result, the first conductive layer 1120-1 in contact with the transparent electrode layer 1110 and the second conductive layer 1120-2 in contact with the second metal layer 1060-2 are formed. That is, the p-type electrode 1130 (the transparent electrode layer 1110 and the first conductive layer 1120-1) in contact with the p-type nitride semiconductor layer 1090, and the n-type electrode 1140 (the second metal layer 1060-2 and the second conductive layer 1120-2) in contact with the first n-type nitride semiconductor layer 1050 are formed (see FIG. 4).

Although the method for manufacturing the light emitting element 1000 of the light emitting device 1 is described based on the flowchart shown in FIG. 11, the method for manufacturing the light emitting element 1000 is not limited to the steps shown in the flowchart. The first conductive layer 1120-1 and the second conductive layer 1120-2 can also be used as wiring arranged in the display portion 10. Therefore, a sealant may be formed before forming the first conductive layer 1120-1 and the second conductive layer 1120-2. That is, the method for manufacturing the light emitting element 1000 may include steps other than steps S1000 to S1130.

According to the method for manufacturing the light emitting device 1 of the present invention, a large-area substrate can be used to form a plurality of light emitting elements 1000 and wiring for connecting the plurality of light emitting elements 1000 in the display portion 10.

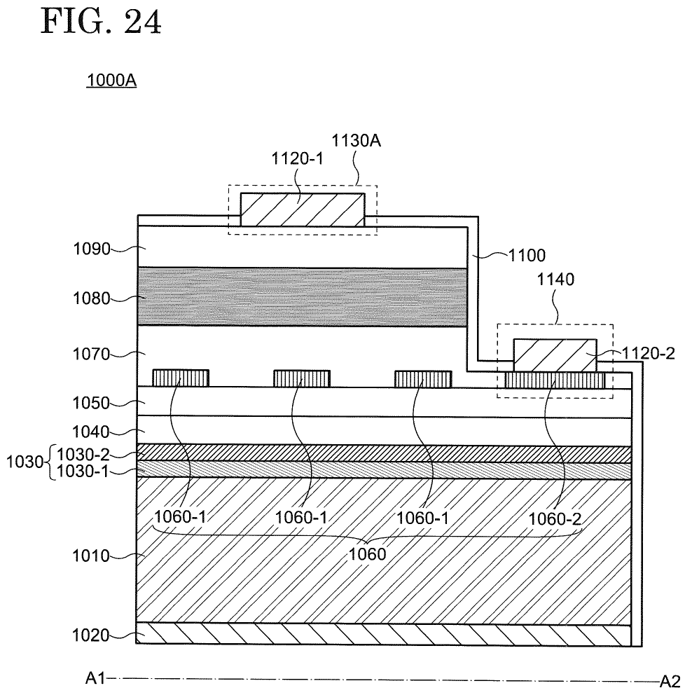

In the present invention, various modifications are possible to the configuration of the light emitting device 1, particularly the light emitting element 1000 included in the light emitting device 1. Hereinafter, some modifications of the light emitting element 1000 are described with reference to FIGS. 24 to 26. In addition, the same configuration as the above-described configuration may be omitted in the following description.

### <Modification 1>

FIG. 24 is a schematic cross-sectional view showing a configuration of a light emitting element 1000A of the light emitting device 1 according to an embodiment of the present invention.

As shown in FIG. 24, the light emitting element 1000A includes the substrate 1010, the compensation layer 1020, the buffer layer 1030, the nitride semiconductor layer 1040, the first n-type nitride semiconductor layer 1050, the metal layer 1060, the second n-type nitride semiconductor layer 1070, the light emitting layer 1080, the p-type nitride semiconductor layer 1090, a p-type electrode 1130A, and the n-type electrode 1140. Compared to the light emitting element 1000, the light emitting element 1000A does not include the transparent electrode layer 1110. Therefore, the p-type electrode 1130A of the light emitting element 1000A is formed only by the first conductive layer 1120-1.

In the case of the configuration of the light emitting element 1000A, the resistance between the p-type nitride semiconductor layer 1090 and the first conductive layer 1120-1 of the p-type electrode 1130A increases. However, since the resistivity of the first conductive layer 1120-1 of the p-type electrode 1130A is sufficiently low, a significant increase in resistance is suppressed. Further, since the first conductive layer 1120-1 can be used as wiring in the display portion 10, a voltage drop caused by resistance in the display portion 10 is suppressed. Therefore, even when the display portion 10 of the light emitting device 1 has a large area, light emission with reduced variation in brightness in the plane is possible.

### <Modification 2>

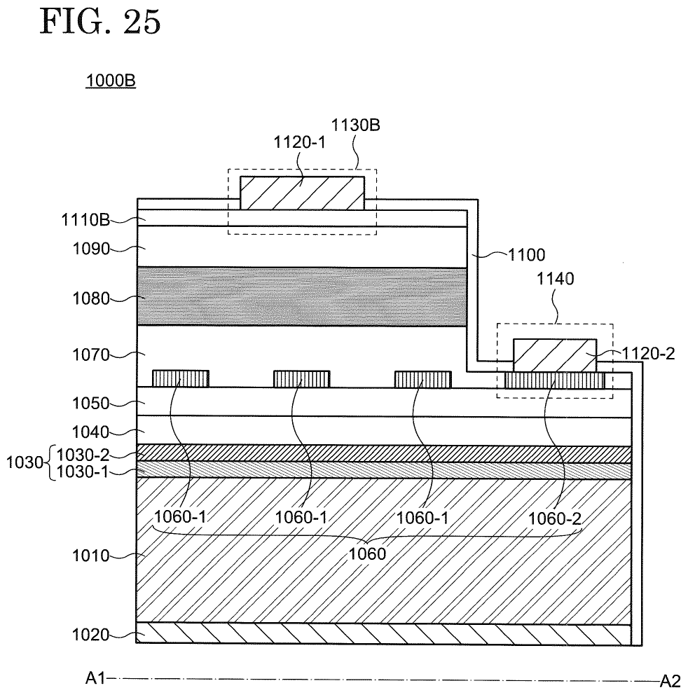

FIG. 25 is a schematic cross-sectional view showing a configuration of a light emitting element 1000B of the light emitting device 1 according to an embodiment of the present invention.

As shown in FIG. 25, the light emitting element 1000B includes the substrate 1010, the compensation layer 1020, the buffer layer 1030, the nitride semiconductor layer 1040, the first n-type nitride semiconductor layer 1050, the metal layer 1060, the second n-type nitride semiconductor layer 1070, the light emitting layer 1080, the p-type nitride semiconductor layer 1090, a p-type electrode 1130B, and the n-type electrode 1140. The p-type electrode 1130B includes a transparent electrode layer 1110B and the first conductive layer 1120-1. The transparent electrode layer 1110B is formed between the p-type nitride semiconductor layer 1090 and the protective layer 1100 so as to cover the entire upper surface of the p-type nitride semiconductor layer 1090.

In the light emitting element 1000B, the first conductive layer 1120-1 is in contact with the transparent electrode layer 1110B, thereby reducing the effective resistivity of the p-type electrode 1130B. Further, since the transparent electrode layer 1110B of the p-type electrode 1130 is in contact with the entire upper surface of the p-type nitride semiconductor layer 1090, holes can be uniformly injected from the p-type electrode 1130B into the surface of the p-type nitride semiconductor layer 1090. Therefore, variation in brightness in the light emitting element 1000B can be reduced.

### <Modification 3>

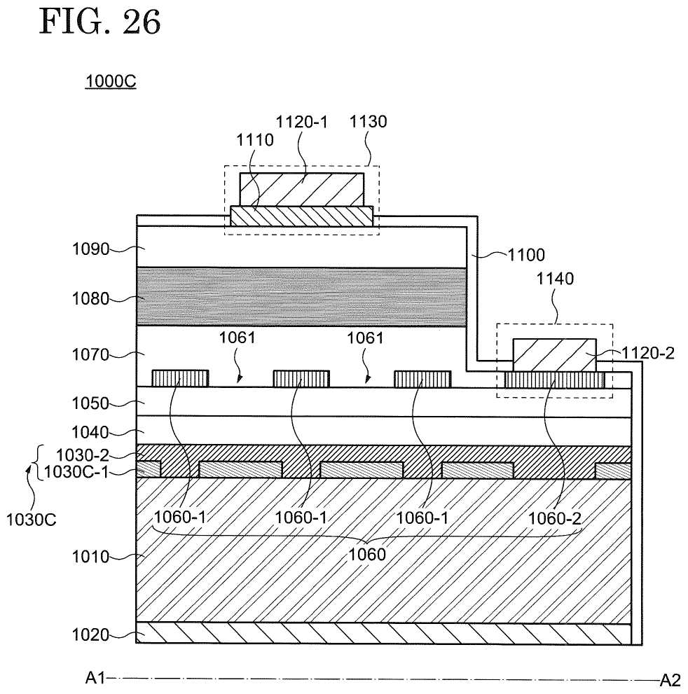

FIG. 26 is a schematic cross-sectional view showing a configuration of a light emitting element 1000C of the light emitting device 1 according to an embodiment of the present invention.

As shown in FIG. 26, the light emitting element 1000C includes the substrate 1010, the compensation layer 1020, a buffer layer 1030C, the nitride semiconductor layer 1040, the first n-type nitride semiconductor layer 1050, the metal layer 1060, the second n-type nitride semiconductor layer 1070, the light emitting layer 1080, the p-type nitride semiconductor layer 1090, the p-type electrode 1130, and the n-type electrode 1140. The buffer layer 1030C of the light emitting element 1000C includes a first buffer layer 1030C-1 and the second buffer layer 1030-2. The first buffer layer 1030C-1 is penetrated in a region overlapping the first metal layer 1060-1. The first buffer layer 1030C-1 completely overlaps the opening portion 1061. That is, the first buffer layer 1030C-1 has a pattern shape in which the region overlapping the first metal layer 1060-1 is perforated, and completely overlaps a portion of the first n-type nitride semiconductor layer 1050 exposed by the opening portions 1061.

In the light emitting element 1000C, it is preferable to use a non-light-transmitting material as the first buffer layer 1030C-1. With this configuration, even when light emitted from the light emitting layer 1080 passes through the opening portions 1061, it is reflected by the first buffer layer 1030C-1, so that the light extraction efficiency from the upper surface of the light emitting device 1 is maintained.

### Second Embodiment

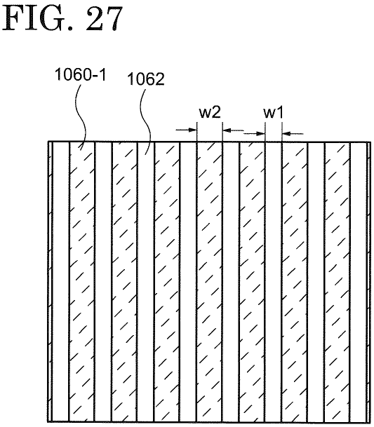

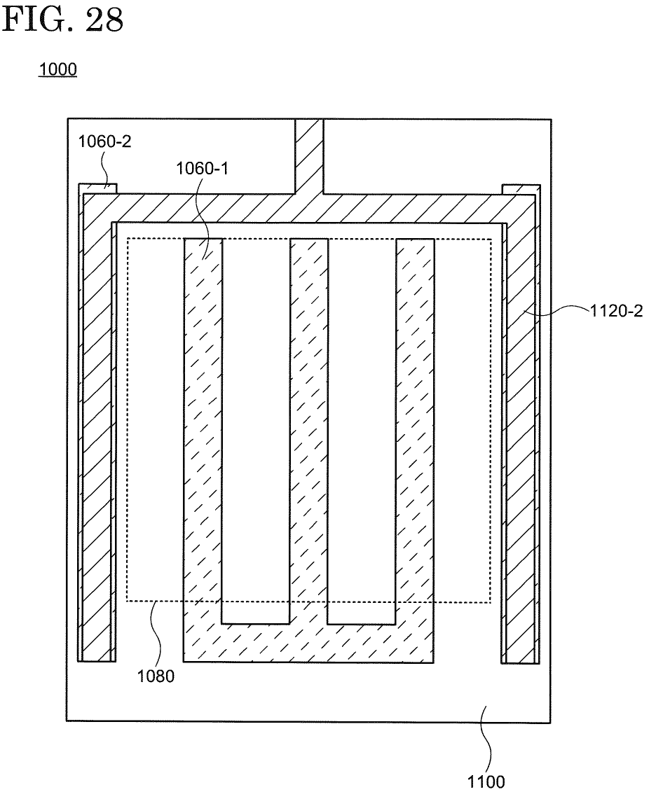

A light emitting device 1 according to an embodiment of the present invention is described with reference to FIGS. 27 and 28. A configuration of the light emitting device 1 described in the Second Embodiment is basically the same as the configuration of the light emitting device 1 described in the First Embodiment. Therefore, the configuration of the light emitting device 1 of the Second Embodiment can be described with reference to FIGS. 1 to 4. However, the light emitting device 1 of the Second Embodiment and the light emitting device 1 of the First Embodiment have different pattern shapes of the metal layer 1060. Therefore, the pattern shape of the metal layer 1060 in the configuration of the light emitting device 1 of the Second Embodiment is mainly described in the following description. In addition, when the configuration of the light emitting device 1 of the Second Embodiment is the same as the configuration of the light emitting device 1 of the First Embodiment, the configuration of the light emitting device 1 of the Second Embodiment may be omitted in the following description.

FIGS. 27 and 28 are schematic plan views showing the pattern shape of the metal layer 1060 in the light emitting element 1000 of the light emitting device 1 according to an embodiment of the present invention. Specifically, FIG. 27 is a plan view showing the pattern shape of the metal layer 1060 in a region overlapping the light emitting layer 1080. Further, FIG. 27 is a plan view showing the pattern shape of the metal layer 1060 in a region not overlapping the light emitting layer 1080.

As shown in FIG. 27, in the region overlapping the light emitting layer 1080, the metal layer 1060 has a pattern shape in which a plurality of groove portions 1062 extending in one direction are formed. The groove portion 1062 is formed between two adjacent first metal layers 1060-1, and the first metal layers 1060-1 extend in one direction. Further, the first n-type nitride semiconductor layer 1050 is exposed in the groove portion 1062. The width w1 of the groove portion 1062 is preferably greater than or equal to 1 μm and less than or equal to 200. Further, the width w2 of the first metal layer 1060-1 (corresponding to the distance between the grooves 1062) is preferably greater than or equal to 5 μm and less than or equal to 1000 μm.

As shown in FIG. 28, ends of the plurality of first metal layers 1060-1 are electrically connected to each other in a region not overlapping the light emitting layer 1080. When the plurality of first metal layers 1060-1 are electrically connected to each other, the potential difference distribution between the plurality of first metal layers 1060-1 becomes small, so that electrons can be uniformly diffused and transported from the first n-type nitride semiconductor layer 1050 to the second n-type nitride semiconductor layer 1070.

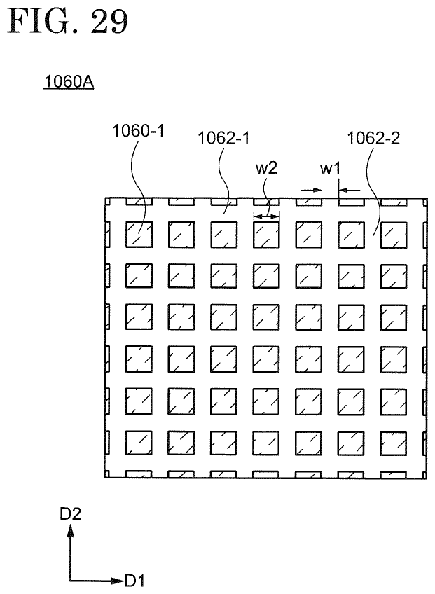

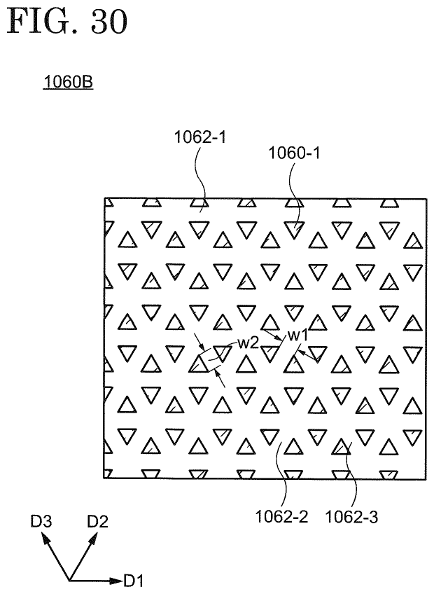

In the present invention, various modifications are possible to the configuration of the light emitting device 1, particularly, the light emitting element 1000 included in the light emitting device 1. Hereinafter, some modifications of the light emitting element 1000 are described with reference to FIGS. 29 and 30. In addition, the same configuration as the above-described configuration may be omitted in the following description.

### <Modification 4>

FIG. 29 is a schematic plan view showing a pattern shape of a metal layer 1060A in the light emitting element 1000 of the light emitting device 1 according to an embodiment of the present invention. Specifically, FIG. 29 is a plan view showing the pattern shape of metal layer 1060A in a region overlapping the light emitting layer 1080.

As shown in FIG. 29, the metal layer 1060A has a pattern shape in which a plurality of first groove portions 1062-1 extending in a first direction D1 and a plurality of second groove portions 1062-2 extending in a second direction D2 are formed. The plurality of first grooves 1062-1 and the plurality of second grooves 1062-2 are orthogonal to each other. That is, the metal layer 1060A has a pattern shape in which the groove portions 1062 are formed in a square lattice shape. In addition, the plurality of first groove portions 1062-1 and the plurality of second groove portions 1062-2 may intersect at a predetermined angle other than 90°. In this case, the groove portions 1062 have a pattern shape formed in a lattice shape rather than a square lattice shape.

In the metal layer 1060A having the pattern shape as shown in FIG. 29, since the groove portions 1062 exposing the first n-type nitride semiconductor layer 1050 are formed symmetrically, homoepitaxial growth is made uniform in the formation of the second n-type nitride semiconductor layer 1070. Further, since the first metal layer 1060-1 is formed in contact with the first n-type nitride semiconductor layer 1050, the resistivity in the plane of the first n-type nitride semiconductor layer 1050 is uniformly reduced. Therefore, the variation among the plurality of light emitting elements 1000 in the display portion 10 of the light emitting device 1 can be suppressed.

### <Modification 5>

FIG. 30 is a plan view showing a pattern shape of the metal layer 1060B in the light emitting element 1000 of the light emitting device 1 according to an embodiment of the present invention. Specifically, FIG. 30 is a plan view showing the pattern shape of the metal layer 1060B in a region overlapping the light emitting layer 1080.

As shown in FIG. 30, the metal layer 1060B has a pattern shape in which a plurality of first groove portions 1062-1 extending in a first direction D1, a plurality of second groove portions 1062-2 extending in a second direction D2, and a plurality of third groove portions 1062-3 extending in a third direction D3 are formed. The plurality of first groove portions 1062-1, the plurality of second groove portions 1062-2, and the plurality of third groove portions 1062-3 intersect each other at an angle of 60°. That is, the metal layer 1060B has the pattern shape in which the groove portions 1062 are formed in a regular triangular lattice shape. In addition, the plurality of first groove portions 1062-1, the plurality of second groove portions 1062-2, and the plurality of third groove portions 1062-3 may intersect each other at a predetermined angle other than 60°. In this case, the groove portions 1062 have a pattern formed in a triangular lattice shape other than a regular triangular lattice shape.

In the metal layer 1060B having the pattern shape as shown in FIG. 30, since the groove portions 1062 exposing the first n-type nitride semiconductor layer 1050 are formed symmetrically, homoepitaxial growth is made uniform in the formation of the second n-type nitride semiconductor layer 1070. Further, since the first metal layer 1060-1 is formed in contact with the first n-type nitride semiconductor layer 1050, the resistivity in the plane of the first n-type nitride semiconductor layer 1050 is uniformly reduced. Therefore, the variation among the plurality of light emitting elements 1000 in the display portion 10 of the light emitting device 1 can be suppressed.

Each of the embodiments described above can be appropriately combined and implemented as long as no contradiction is caused. Further, the addition, deletion, or design change of components, or the addition, deletion, or condition change of processes as appropriate by those skilled in the art based on each of the embodiments are also included in the scope of the present invention as long as they are provided with the gist of the present invention.

It is understood that, even if the effect is different from those provided by each of the above-described embodiments, the effect obvious from the description in the specification or easily predicted by persons ordinarily skilled in the art is apparently derived from the present invention.

What is claimed is:

1. A light emitting device, comprising:
a substrate;
a buffer layer over the substrate;
a nitride semiconductor layer over the buffer layer;
a first n-type nitride semiconductor layer over the nitride semiconductor layer;
a metal layer over the first n-type nitride semiconductor layer;
a second n-type nitride semiconductor layer over the metal layer;
a light emitting layer over the second n-type nitride semiconductor layer; and
a p-type nitride semiconductor layer over the light emitting layer,
wherein the metal layer has a pattern shape in which a portion of the first n-type nitride semiconductor layer is exposed, and
wherein the second n-type nitride semiconductor layer is in contact with the portion of the first n-type nitride semiconductor layer exposed from the metal layer.

2. The light emitting device according to claim 1, wherein the pattern shape comprises a plurality of opening portions.

3. The light emitting device according to claim 2, wherein the plurality of opening portions are arranged in a square lattice pattern or a regular triangular lattice pattern.

4. The light emitting device according to claim 1, wherein the pattern shape comprises a plurality of groove portions.

5. The light emitting device according to claim 4,
wherein the metal layer comprises a plurality of straight portions separated by the plurality of groove portions in a region overlapping the light emitting layer, and
wherein the plurality of straight portions are electrically connected to each other in a region not overlapping the light emitting layer.

6. The light emitting device according to claim 1,
wherein the pattern shape comprises:
a plurality of first groove portions extending in a first direction; and
a plurality of second groove portions extending in a second direction different from the first direction and intersecting with the plurality of first groove portions.

7. The light emitting device according to claim 6, wherein the pattern shape further comprises a plurality of third groove portions extending in a third direction different from the first direction and the second direction and intersecting with the plurality of first groove portions and the plurality of second groove portions.

8. The light emitting device according to claim 1,
wherein the buffer layer comprises:
a first buffer layer including a first conductive material; and
a second buffer layer including an insulating material over the buffer layer.

9. The light emitting device according to claim 8,
wherein the first buffer layer has a pattern shape in which a region overlapping the metal layer is penetrated, and
wherein the first buffer layer completely overlaps the portion of the first n-type nitride semiconductor layer.

10. The light emitting device according to claim 1, further comprising:
an n-type electrode in contact with the first n-type nitride semiconductor layer; and
a p-type electrode in contact with the p-type nitride semiconductor layer,
wherein the n-type electrode comprises a portion of the metal layer, and
wherein each of the n-type electrode and the p-type electrode comprises copper.

11. The light emitting device according to claim 10, wherein the p-type electrode comprises a transparent conductive oxide in contact with the p-type nitride semiconductor layer.

12. The light emitting device according to claim 1, wherein the metal layer comprises titanium.

13. A method for manufacturing a light emitting device, comprising the steps of:
forming a buffer layer over a substrate;
forming a first n-type nitride semiconductor layer over the buffer layer;
forming a metal layer having a pattern shape in which a portion of the first n-type nitride semiconductor layer is exposed, over the first nitride semiconductor layer;
forming a second n-type nitride semiconductor layer in contact with the portion of the first n-type nitride semiconductor layer exposed from the metal layer, over the metal layer;
forming a light emitting layer over the second n-type nitride semiconductor layer; and
forming a p-type nitride semiconductor layer over the light emitting layer.

14. The method for a light emitting device according to claim 13, wherein the pattern shape comprises a plurality of opening portions.

15. The method for a light emitting device according to claim 13, wherein the pattern shape comprises a plurality of groove portions.

16. The method for a light emitting device according to claim 13,
wherein the formation of the buffer layer comprises:
forming a first buffer layer including a conductive material; and
forming a second buffer layer including an insulating material over the first buffer layer.

17. The method for manufacturing a light emitting device according to claim 16,
wherein the first buffer layer has a pattern shape in which a region overlapping the metal layer is penetrated, and
wherein the first buffer layer completely overlaps the portion of the first n-type nitride semiconductor layer.

18. The method for manufacturing a light emitting device according to claim 13, further comprising the steps of:
etching the p-type nitride semiconductor layer, the light emitting layer, and the second n-type nitride semiconductor layer so that a portion of the metal layer is exposed;
forming a p-type electrode in contact with the p-type nitride semiconductor layer; and
forming an n-type electrode in contact with the first nitride semiconductor layer, the n-type electrode comprising the portion of the metal layer,
wherein each of the p-type electrode and the n-type electrode comprises copper.

19. The method for a light emitting device according to claim 18, wherein the p-type electrode comprises a transparent conductive oxide in contact with the p-type nitride semiconductor layer.

20. The method for a light emitting device according to claim 13, wherein the metal layer comprises titanium.
